(19) United States
(12) Patent Application Publication
(10) Pub. No.: US 2015/0206705 A1
(43) Pub. Date: Jul. 23, 2015

(54) MEMBER FOR CHARGED PARTICLE BEAM DEVICE, CHARGED PARTICLE BEAM DEVICE AND DIAPHRAGM MEMBER

(71) Applicant: Hitachi High-Technologies Corporation, Minato-ku, Tokyo (JP)

(72) Inventors: Noriyuki Sakuma, Tokyo (JP); Yusuke Ominami, Tokyo (JP)

(73) Assignee: Hitachi High- Technologies Corporation, Minato-ku, Tokyo (JP)

(21) Appl. No.: 14/423,367

(22) PCT Filed: Jul. 11, 2013
(86) PCT No.: PCT/JP2013/069050

§ 371 Date: Feb. 23, 2015

(30) Foreign Application Priority Data
Sep. 5, 2012 (JP) 2012-194664

(51) Int. Cl. H01J 37/20; H01J 37/18; H01J 37/28

(52) U.S. Cl. CPC H01J 37/20; H01J 37/28; H01J 37/18; H01J 2237/2006; H01J 2237/063; H01J 2237/1825; H01J 2237/2801

(57) ABSTRACT

A member for a charged particle beam device (56), which is used for a charged particle beam device (1c), includes a frame (55) to be attached to a frame (3c), and a diaphragm element (18a) provided in the frame (55). In the diaphragm element (18a), a diaphragm (19), which air-tightly separates the inside and the outside of a vacuum chamber (4a) from each other in a state where the pressure inside the vacuum chamber (4a) partitioned by the frame (3c) and the frame (55) is reduced more than the pressure outside the vacuum chamber (4a), and allows a charged particle beam to be transmitted therethrough, is formed. Moreover, in the diaphragm element (18a), a buffer film (33) for preventing a sample (12) and the diaphragm (19) from coming into contact with each other is formed so as to be positioned on a sample stage (22) side rather than on the diaphragm (19).

### TECHNICAL FIELD

The present invention relates to a charged particle beam device, and in particular to such a charged particle beam device capable of observing a sample in a non-vacuum state.

### BACKGROUND ART

In order to observe a portion in a microscopic region on an object in an enlarged state, a charged particle beam device, such as a scanning electron microscope (SEM) and a transmission electron microscope (TEM), has been used. In such charged particle beam devices, a sample (sample to be observed) is disposed in a vacuum chamber that is air-tightly provided, and the sample is observed in a state that the pressure inside the vacuum chamber is reduced to vacuum, that is, in a vacuum state, while an electron beam is being radiated from an electron optical system disposed inside the vacuum chamber.

On the other hand, with respect to a sample with moisture contained therein in the biochemical field or a liquid-state sample, etc., which is damaged or denatured in the vacuum state, there have been demands for carrying out an observation while an electron beam is being radiated thereto. Therefore, in recent years, a SEM has been developed in which a sample can be observed in a non-vacuum state, such as under the atmospheric pressure, while an electron beam is being radiated thereto.

In the SEM of this type, a vacuum chamber in which an electron optical system is disposed and a space in which a sample is disposed are separated from each other by a diaphragm or minute through-holes through which an electron beam can be transmitted, so that the inside of the vacuum chamber is brought to a vacuum state, while maintaining the space with the sample being placed therein in a non-vacuum state such as under the atmospheric pressure.

For example, Japanese Patent Application Publication No. 2009-158222 (Patent Document 1) has disclosed a technique in which, with respect to a SEM, a sample holding member, with a sample holding film (diaphragm) formed therein, is provided on an upper portion of a charged particle optical lens barrel that is a vacuum chamber, and the inside of the vacuum chamber is brought into a vacuum state. In the SEM described in Patent Document 1, to a sample held on the sample holding film under atmospheric pressure, an electron beam is radiated through the sample holding film so that by detecting reflected electrons and secondary electrons generated from the sample, an observation process is carried out.

On the other hand, Japanese Patent Application National Publication (Laid-Open) No. 2010-509709 (Patent Document 2) has disclosed a technique in which, in a SEM for observing an object in a non-vacuum environment, apertures (diaphragm elements) for allowing an electron beam to be transmitted are formed between a vacuum environment and a non-vacuum environment in which an object is disposed on a lower portion of the vacuum environment. In the SEM described in Patent Document 2, in a scanning transmission electron microscope (STEM) mode, by using a spacer that is disposed on the periphery of an aperture, with its height designed to determine an operation distance, a controlling process is carried out so as to obtain the maximum resolution.

### RELATED ART DOCUMENTS

### Patent Documents

Patent Document 1: Japanese Patent Application Publication No. 2009-158222

Patent Document 2: Japanese Patent Application National Publication (Laid-Open) No. 2010-509709

### SUMMARY OF THE INVENTION

### Problems to be Solved by the Invention

In accordance with examinations of the present inventors, the following facts have been found out.

In a SEM having the same configuration as that of the SEM described in the above-mentioned Patent Document 1, it is necessary to re-mount a sample on a diaphragm many times until a portion to be desirably observed has been mounted on the diaphragm. Moreover, in the case when the diaphragm is damaged, the sample might enter the charged particle optical lens barrel placed on the lower portion thereof.

On the other hand, in a SEM having the same configuration as that of the SEM described in the above-mentioned Patent Document 2, since this configuration is different from that in which a sample is mounted on a diaphragm and held thereon, it is not necessary to re-mount a sample on the diaphragm. However, for adjusting a focal point at a high magnification, the sample held on the sample stage needs to be made closer to the diaphragm element, with the result that the diaphragm and the sample are easily made in contact with each other to easily cause damages in the diaphragm. Alternatively, upon attaching the diaphragm element to the charged particle beam device, or upon exchanging the diaphragm elements, the diaphragm tends to be easily made in contact with another member, with the result that the diaphragm tends to be easily damaged.

Moreover, due to a change in a composition of a gas positioned between the diaphragm element and the sample or a change in the pressure, the focal point distance fluctuates in some cases. For this reason, every time an observation image is captured, the distance between the diaphragm element and the sample needs to be adjusted, and moreover, the diaphragm and the sample tends to more easily come into contact with each other, with the result that the diaphragm is more easily damaged.

However, in the SEM described in the aforementioned Patent Document 2, the spacer disposed on the periphery of an aperture is used for keeping the constant distance between the diaphragm and the sample, and is not used for preventing the diaphragm from coming into contact with the sample.

In the case when the diaphragm and the sample are easily made in contact with each other, the diaphragm is easily damaged, and since the observed image cannot be captured stably with a high resolution, the performance of the charged particle beam device is lowered.

In view of these problems, the present invention provides a charged particle beam device, in the charged particle beam device capable of observing a sample in a non-vacuum state, that make it possible to prevent the diaphragm from coming into contact with the sample or another member, and to capture an observed image stably with a high resolution.

### Means for Solving the Problems

A member for a charged particle beam device in accordance with a typical embodiment, which is used for the charged particle beam device, includes a second frame attached to a first frame and a diaphragm element provided in the second frame. On the diaphragm element, a diaphragm, which, when the second frame is attached to the first frame, air-tightly separates the inside and the outside of the vacuum chamber from each other in a state that the pressure inside the vacuum chamber partitioned by the first frame and the second frame is reduced more than the pressure outside the vacuum chamber, and allows a charged particle beam to be transmitted therethrough, is formed. Onto the diaphragm element, a buffer film for preventing the sample and the diaphragm from coming into contact with each other is formed so as to be positioned on a sample stage side rather than on the diaphragm side.

Moreover, a charged particle beam device in accordance with a typical embodiment includes a diaphragm element attached to a wall portion of the vacuum chamber. Onto the diaphragm element, a diaphragm, which air-tightly separates the inside and the outside of the vacuum chamber from each other in a state that the pressure inside the vacuum chamber is reduced more than the pressure outside the vacuum chamber, and allows a charged particle beam to be transmitted therethrough, is formed. Onto the diaphragm element, a buffer film for preventing the sample and the diaphragm from coming into contact with each other is formed so as to be positioned on a sample stage side rather than on the diaphragm side.

Furthermore, a diaphragm element in accordance with a typical embodiment is attached to a wall portion of the charged particle beam device. Onto the diaphragm element, a diaphragm, which air-tightly separates the inside and the outside of the vacuum chamber from each other in a state that the pressure inside the vacuum chamber is reduced more than the pressure outside the vacuum chamber, and allows a charged particle beam to be transmitted therethrough, when the diaphragm element is attached to the wall portion of the vacuum chamber, is formed. Onto the diaphragm element, a buffer film for preventing the sample and the diaphragm from coming into contact with each other is formed so as to be positioned on a sample stage side rather than on the diaphragm.

### Effects of the Invention

In accordance with the typical embodiments, a charged particle beam device, which is capable of observing a sample in a non-vacuum state, makes it possible to prevent the diaphragm from coming into contact with the sample or another member, and to capture an observed image stably with a high resolution.

### BRIEF DESCRIPTIONS OF THE DRAWINGS

FIG. 1 is an overall structural view of a charged particle beam device in accordance with a first embodiment;

FIG. 2 is a view showing a configuration on the periphery of a diaphragm element and a sample stage of the charge particle beam device in accordance with the first embodiment;

FIG. 3 is a cross-sectional view showing main parts of the diaphragm element in accordance with the first embodiment;

FIG. 4 is a plan view of the diaphragm element in accordance with the first embodiment when seen from the sample side;

FIG. 5 is a plan view of the diaphragm element in accordance with a first modification example of the first embodiment when seen from the sample side;

FIG. 6 is a plan view of the diaphragm element in accordance with a second modification example of the first embodiment when seen from the sample side;

FIG. 7 is a plan view of the diaphragm element in accordance with a third modification example of the first embodiment when seen from the sample side;

FIG. 8 is a cross-sectional view showing main parts of the diaphragm element in a manufacturing process in accordance with the first embodiment;

FIG. 9 is a cross-sectional view showing main parts of the diaphragm element in a manufacturing process in accordance with the first embodiment;

FIG. 10 is a cross-sectional view showing main parts of the diaphragm element in a manufacturing process in accordance with the first embodiment;

FIG. 11 is a cross-sectional view showing main parts of the diaphragm element in a manufacturing process in accordance with the first embodiment;

FIG. 12 is a cross-sectional view showing main parts of the diaphragm element in a manufacturing process in accordance with the first embodiment;

FIG. 13 is a cross-sectional view showing main parts of the diaphragm element in a manufacturing process in accordance with the first embodiment;

FIG. 14 is a cross-sectional view showing main parts of the diaphragm element in a manufacturing process in accordance with the first embodiment;

FIG. 15 is a cross-sectional view showing main parts of the diaphragm element in accordance with a fourth modification example of the first embodiment;

FIG. 16 is a cross-sectional view showing main parts of the diaphragm element in accordance with a fifth modification example of the first embodiment;

FIG. 17 is a cross-sectional view showing main parts of the diaphragm element in accordance with a sixth modification example of the first embodiment;

FIG. 18 is a cross-sectional view showing main parts of the diaphragm element in accordance with a seventh modification example of the first embodiment;

FIG. 19 is a flowchart showing parts of an observing process of the charged particle beam device in accordance with the first embodiment;

FIG. 20 is a view showing a configuration on the periphery of a diaphragm element and a sample stage of the charged particle beam device in accordance with a second embodiment;

FIG. 21 is a plan view showing an attachment in accordance with the second embodiment when seen from the sample side;

FIG. 22 is a cross-sectional view showing main parts taken along the line B-B of FIG. 21;

FIG. 23 is an overall structural view of a charged particle beam device in accordance with a third embodiment;

FIG. 24 is an overall structural view of a scanning electron microscope in accordance with a fourth embodiment;

FIG. 25 is a flowchart showing parts of an observing process of the scanning electron microscope in accordance with the fourth embodiment;

FIG. 26 is an overall structural view of the scanning electron microscope in the observing process in accordance with the fourth embodiment; and

FIG. 27 is an overall structural view of a scanning electron microscope in accordance with a fifth embodiment.

### DETAILED DESCRIPTION OF PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that members having the same function are denoted by the same reference symbols throughout all drawings for describing the embodiments, and the repetitive description thereof will be omitted. In addition, the description of the same or similar portions is not repeated in principle unless particularly required in the following embodiments.

Further, in some drawings used in the embodiments, hatching is omitted in some cases even in a cross-sectional view so as to make the drawings easy to see. Still further, hatching is used in some cases even in a plan view so as to make the drawings easy to see.

Additionally, in the respective embodiments to be explained below, explanations will be given by exemplifying a charged particle beam device that is applied to a charged particle beam microscope composed of a scanning electron microscope (SEM) using an electron beam as a primary charged particle beam. However, the respective embodiments may be applicable to other various kinds of charged particle beam devices such as a SIM (Scanning Ion Microscope) that radiates an ion beam to a sample as a primary charged particle beam and detects secondary electrons and reflected electrons that are secondarily generated, or an ion microscope using an ionic beam. Moreover, the respective embodiments to be explained below may be combined with one another appropriately within a scope without departing from the gist of the present invention.

### First Embodiment

### Configuration of Charged Particle Beam Device

Referring to the drawings, a charged particle beam device in accordance with one embodiment of the present invention will be explained. As described earlier, in the following description, examples in which a charged particle beam device is applied to a SEM will be explained.

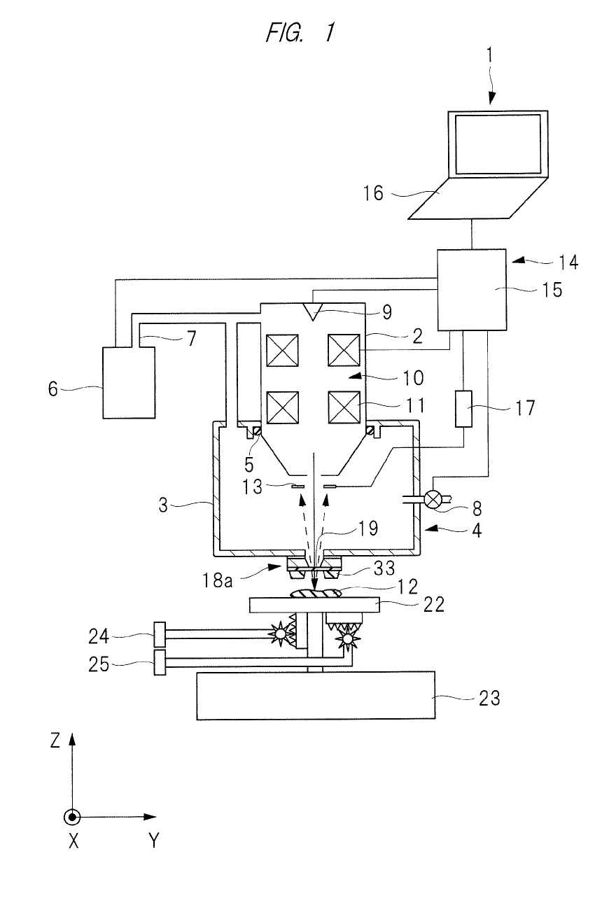

FIG. 1 is an overall structural view of a charged particle beam device in accordance with a first embodiment.

As shown in FIG. 1, a charged particle beam device 1 includes a charged particle optical lens barrel 2 and a frame 3. By the charged particle optical lens barrel 2 and the frame 3, a vacuum chamber 4 is partitioned.

The charged particle optical lens barrel 2 is provided, for example, on the upper side of the frame 3, with the lower portion of the charged particle optical lens barrel 2 being made to protrude inside the frame 3. The charged particle optical lens barrel 2 is attached to the frame 3 through a sealing member (O-ring) 5, and a vacuum chamber 4 partitioned by the charged particle optical lens barrel 2 and the frame 3 is air-tightly provided.

Onto the outside of the vacuum chamber 4 partitioned by the charged particle optical lens barrel 2 and the frame 3, a vacuum pump (exhaust unit) 6 is provided. The vacuum pump 6 is connected to the charged particle optical lens barrel 2 and the frame 3 by using a vacuum pipe 7. That is, the vacuum pump 6 is connected to the vacuum chamber 4.

At the time of the use of the charged particle beam device 1, the vacuum chamber 4 is exhausted by the vacuum pump 6 so that the pressure inside the vacuum chamber 4 is reduced to a vacuum state. That is, the vacuum chamber 4 is exhausted by the vacuum pump 6 so that the pressure inside the vacuum chamber 4 is kept in a reduced pressure state more than the pressure outside the vacuum chamber 4.

Additionally, only one vacuum pump (exhaust unit) 6 is shown; however, two or more vacuum pumps 6 may be provided.

A leak valve 8 is provided on the frame 3. The leak valve 8 is used for releasing the vacuum chamber 4 partitioned by the charged particle optical lens barrel 2 and the frame 3 to the atmosphere. At the time of maintenance or the like, the inside of the frame 3 can be released to the atmosphere by the leak valve 8. The leak valve 8 may not be provided, or two or more leak valves 8 may be provided. Moreover, the layout position of the leak valve 8 in the frame 3 is not limited by a place indicated by FIG. 1. That is, the leak valve 8 may be disposed at another position of the frame 3.

Inside the charged particle optical lens barrel 2, a charged particle source 9 and a charged particle optical system 10 are formed. The charged particle source 9 generates a charged particle beam. In the case when the charged particle beam device 1 is a SEM, the charged particle source 9 is an electron source for generating an electron beam, and composed of an electron gun including, for example, filaments. The charged particle optical system 10 is constituted by elements such as an optical lens 11, etc. The charged particle optical system 10 converges a charged particle beam generated by the charged particle source 9, and radiates this to a sample 12, and scans on the sample 12 as a primary charged particle beam. That is, the charged particle optical system 10 radiates the charged particle beam generated by the charged particle source 9 so as to scan the sample 12.

On a portion of the charged particle optical lens barrel 2 protruding to the inside of the frame 3, a detector 13 is provided. By radiating a primary charged particle beam to the sample 12, the detector 13 detects secondary charged particles (secondary electrons or reflected electrons) discharged (generated) from the sample 12. The detector 13 amplifies and detects charged particles flying and coming with an energy of, for example, several keV to several tens of keV. Since the detector 13 is desirably designed to be thin and flat, a semiconductor detector made of, for example, a semiconductor material such as silicon, or a scintillator or the like capable of converting a signal derived from charged particles into light by a glass surface or inside thereof can be used as the detector 13.

Moreover, on the charged particle beam device 1 of the first embodiment, a control unit 15 and a personal computer 16 are provided as a control system 14. The control unit 15 controls the vacuum pump (exhaust unit) 6, the charged particle optical system 10, etc. The personal computer 16 includes a monitor on which an operation screen (Graphical User Interface: GUI) for use in operating the charged particle beam device 1 is displayed and an input unit for use in inputting a command to the operation screen from the user, such as a keyboard and a mouse. The personal computer 16 is connected to the control unit 15 by a communication line. Additionally, the control unit 15 has a built-in analog circuit and a digital circuit so that output signals from the vacuum pump 6, the charged particle source 9, the optical lens 11 and the detector 13 are converted to digital image signals, and transmitted to the personal computer 16.

As shown in FIG. 1, the detector 13 may be connected to the control unit 15 by way of an amplifier 17, such as a preamplifier, and in this case, an output signal from the detector 13 is sent to the control unit 15 by way of, for example, the amplifier 17. Alternatively, in the case when the amplifier 17 is unnecessary, the output signal from the detector 13 need not necessarily be sent to the control unit 15 by way of the amplifier 17.

Additionally, the configuration of the control system 14 shown in FIG. 1 is only exemplary. Therefore, modification examples with respect to a valve (the illustration thereof is omitted) provided in the midway between the control unit 15 and the vacuum pipe 7, the vacuum pump 6 or respective communication lines, etc., fall within the scope of the charged particle beam device of the first embodiment without departing from the gist of the first embodiment.

### Outside of Vacuum Chamber

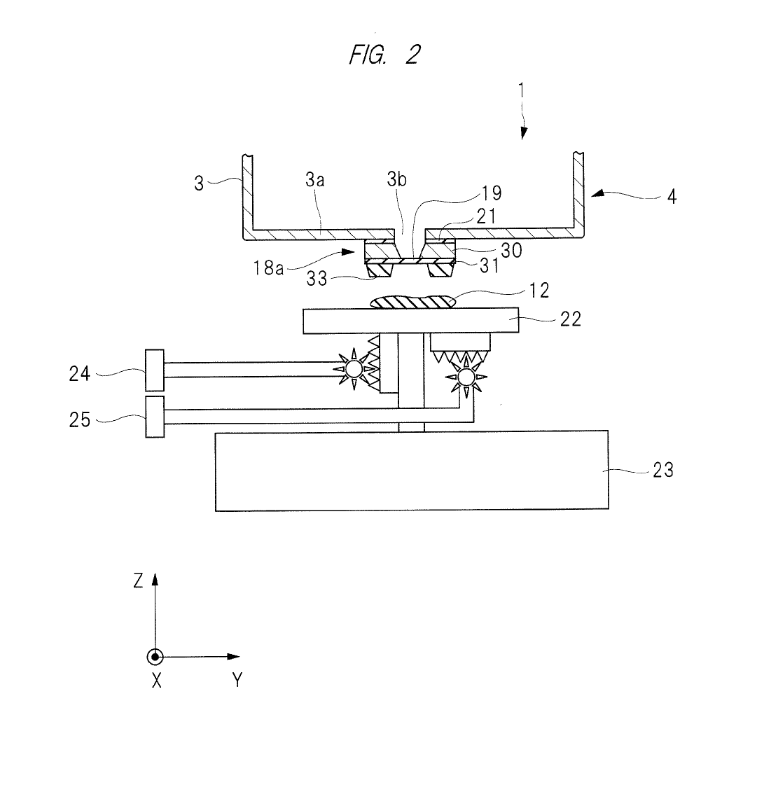

FIG. 2 is a view showing a configuration on the periphery of the diaphragm element and sample stage of the charged particle beam device in accordance with the first embodiment.

In the frame 3, a diaphragm element (diaphragm member) 18a is provided. In examples shown in FIG. 1 and FIG. 2, on a portion positioned below the charged particle optical lens barrel 2 that is the lower surface portion (wall portion of the vacuum chamber 4) 3a of the frame 3, the diaphragm element 18a is provided. Although the detailed configuration of the diaphragm element 18a will be described later, the diaphragm element 18a includes a diaphragm (membrane, film portion) 19 for allowing a primary charged particle beam to transmit or pass therethrough, and air-tightly separates the space inside the vacuum chamber 4 and the space outside the vacuum chamber 4 from each other.

On a portion positioned below the charged particle optical lens barrel 2 that is the lower surface portion 3a of the frame 3, an opening portion 3b for allowing a primary charged particle beam to transmit or pass therethrough is formed, and the diaphragm element 18a is attached thereto in a manner so as to shield the opening portion 3b. In the center of the diaphragm element 18a, the diaphragm (film portion) 19 for allowing the primary charged particle beam to transmit or pass therethrough is formed. The diaphragm element 18a is attached to the lower surface portion 3a of the frame 3, with the peripheral portion of the diaphragm 19 being bonded to the peripheral portion of the opening portion 3b that is the lower surface portion 3a of the frame 3 by a bonding member 21.

The bonding member 21 desirably seals a portion between the diaphragm element 18a and the lower surface portion 3a of the frame 3 air-tightly. The bonding member 21 is designed to air-tightly seal a portion between the diaphragm element 18a and the lower surface portion 3a of the frame 3, at the time of use of the charged particle beam device 1 in a state where the pressure inside the vacuum chamber 4 is reduced more than the pressure outside the vacuum chamber 4. Moreover, the bonding member 21 is also designed to bond the diaphragm element 18a so as not to come off the lower surface portion 3a of the frame 3 even in the case when the inside of the vacuum chamber 4 is returned to the atmospheric pressure at the time of maintenance of the charged particle beam device 1. As the bonding member 21 having such sealing strength and bonding strength, for example, a member containing a material such as silicone rubber, silver paste, vacuum grease, epoxy resin or silicone resin, may be used.

On a portion positioned below the diaphragm element 18a that is the outside of the vacuum chamber 4 partitioned by the charged particle optical lens barrel 2 and the frame 3, a sample stage (holding unit) 22 is provided. The sample stage 22 is used for holding the sample 12 outside the vacuum chamber 4. The sample stage 22 is assembled on a mount portion 23.

Moreover, a Z-axis driving unit 24 and X, Y-axes driving unit 25 are provided on the outside of the vacuum chamber 4. The Z-axis driving unit 24 drives the sample stage 22 to move, for example, in the Z-axis direction corresponding to a perpendicular direction so that by changing the height position of the sample stage 22, the distance between the sample 12 held on the sample stage 22 and the diaphragm element 18a along the z-axis direction is adjusted. By driving the sample stage 22 to move, for example, in each of the X-axis direction and the Y-axis direction that are two directions intersecting with each other on a horizontal plane, the X, Y-axes driving unit 25 moves the sample 12 held on the sample stage 22 in the X-axis direction as well as in the Y-axis direction.

At the time of the use of the charged particle beam device 1, the sample 12 is held, with being mounted on the stage 22, and by using the Z-axis driving unit 24, the height position of the sample 12 is adjusted so that the sample 12 can be observed clearly. Moreover, by adjusting the X, Y-axes driving unit 25, the sample 12 is moved to a desired position, while observing the image thereof.

Additionally, in the first embodiment, by allowing the Z-axis driving unit 24 to drive and move the sample stage 22, the distance between the sample 12 held on the sample stage 22 and the diaphragm element 18a along the Z-axis direction is adjusted. However, for example, by allowing the Z-axis driving unit 24 to drive and move not the sample stage 22, but the diaphragm element 18a, together with, for example, the frame 3, the distance between the sample 12 held on the sample stage 22 and the diaphragm element 18a along the Z-axis direction may be adjusted.

In the charged particle beam device 1 of the first embodiment, by exhausting the vacuum chamber 4 that is partitioned by the charged particle optical lens barrel 2 and the frame 3 and air-tightly provided by the vacuum pump (exhaust unit) 6, the pressure inside the vacuum chamber 4 is maintained in a reduced-pressure state more than the pressure of the space in which the sample 12 is disposed. Moreover, in a state where there is a pressure difference between the inside of the vacuum chamber 4 and the space in which the sample 12 is disposed, a primary charged particle beam passing through the inside of the vacuum chamber 4 and transmitting the diaphragm element 18a provided in the frame 3 is radiated to the sample 12 held on the outside of the vacuum chamber 4 so as to scan the sample 12.

### Diaphragm Element

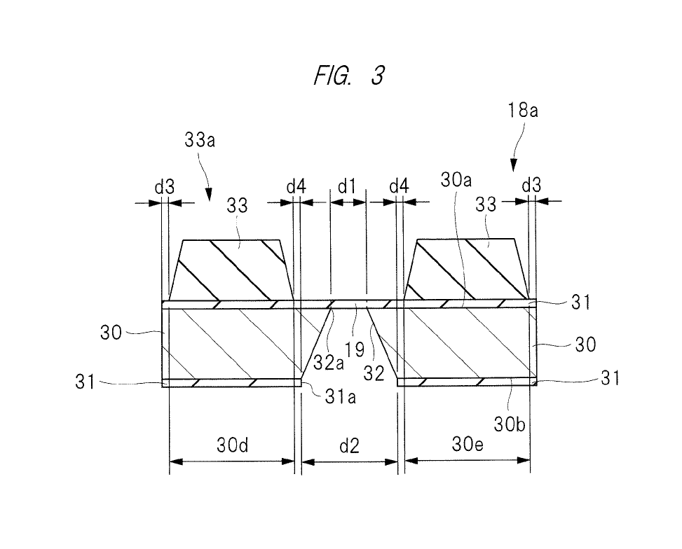

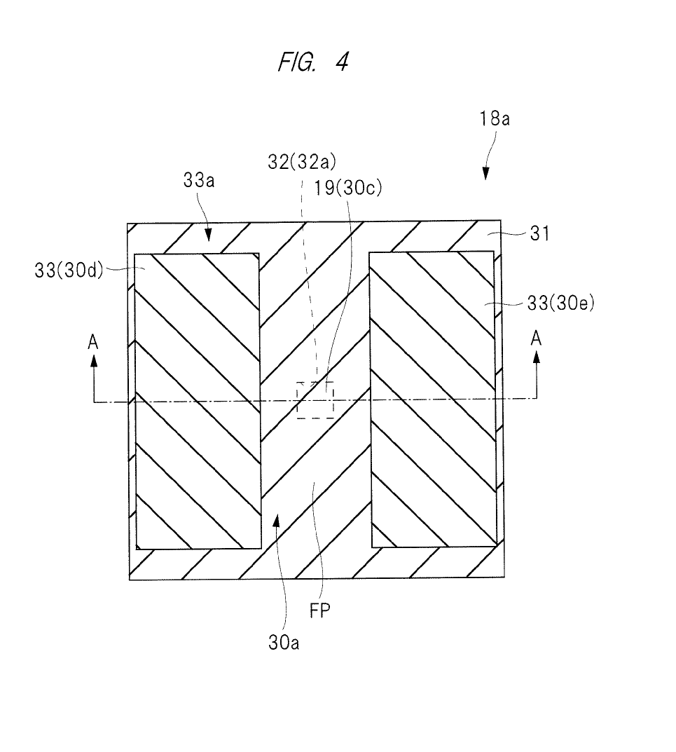

FIG. 3 is a cross-sectional view showing main parts of the diaphragm element in accordance with the first embodiment. FIG. 4 is a plan view of the diaphragm element in accordance with the first embodiment when seen from the sample side. Additionally, FIG. 3 is a cross-sectional view showing the main parts taken along an A-A line of FIG. 4. In FIG. 3, the diaphragm element 18a is illustrated in an upside-down inverted state from the state in which it is attached to the lower surface portion (wall portion of the vacuum chamber 4) 3a (see FIG. 2) of the frame 3.

The diaphragm element (diaphragm member) 18a includes a holding substrate (base substrate) 30 as abase substrate supporting the entire diaphragm element 18a. The holding substrate 30 has a main surface 30a and a main surface 30b on the opposite side of the main surface 30a. The main surface 30a faces the outside of the vacuum chamber 4, when the diaphragm element 18a is attached to the lower surface portion 3a (see FIG. 2) of the frame 3.

Thin films 31 are formed on the main surface 30a and the main surface 30b of the holding substrate 30, that is, on the two surfaces of the holding substrate 30. On the thin film 31 formed on the main surface 30b of the holding substrate 30, an opening portion 31a that penetrates the thin film 31 to reach the holding substrate 30 is formed, and in the opening portion 31a, a through-hole 32, which reaches the main surface 30a from the main surface 30b after the holding substrate 30 is removed, is formed. Of the thin film 31 formed on the main surface 30a of the holding substrate 30, a portion, which is remained so as to cover the opening 32a of the through hold 32 of the main surface 30a, becomes the aforementioned diaphragm (membrane, film portion) 19. That is, the diaphragm 19 is formed on the main surface 30a in a manner so as to cover the opening 32a of the through-hole 32 on the main surface 30a.

Moreover, desirably, the opening portion 31a is formed on a position corresponding to the center of the main surface 30b of the holding substrate 30, when seen in a plan view, so that the through-hole 32 is formed in the center of the holding substrate 30, when seen in a plan view. That is, the diaphragm 19 is formed in the center of the main surface 30a of the holding substrate 30, when seen in a plan view. By forming the through-hole 32 in the center of the holding substrate 30, the strength of the diaphragm element 18a can be improved.

As the holding substrate (base substrate) 30, desirably, a substrate, which is a semiconductor substrate (Si substrate) made of, for example, a single crystal silicon (Si), with the orientation of the main surface 30a and the main surface 30b, that is, the substrate orientation, being set to (100) or (110), is used. Thus, by carrying out an anisotropic etching process using an etching liquid composed of an alkaline aqueous solution, as described later, the through-hole 32 can be easily formed in the holding substrate 30. Moreover, since the side face of the through-hole 32 forms a (111) plane, the through-hole 32 can be formed with a good shape accuracy. Furthermore, a substrate whose two surfaces are finished into mirror surfaces may be used as the holding substrate 30. Thus, a machining process can be easily carried out on the two surfaces of the holding substrate 30.

Additionally, as shown in FIG. 3 and FIG. 4, the thin film 31 may be formed on the entire surface of the main surface 30a of the holding substrate 30; however, it is only necessary to form, the thin film 31 to cover at least the opening 32a of the through-hole 32. In the following description, an explanation will be given by exemplifying only the portion of the thin film 31 formed in a manner so as to cover the opening 32a of the through-hole 32 of the main surface 30a as the diaphragm (film portion) 19.

When the thickness of the diaphragm 19 becomes thinner, it becomes difficult to form the diaphragm 19 with good precision in the thickness dimension. In contrast, when the thickness of the diaphragm 19 becomes thicker, the primary charged particle beam passing through the inside of the vacuum chamber 4 and the secondary charged particles discharged from the sample 12 are hardly allowed to transmit or pass through the diaphragm 19, with the result that the amount of the primary charged particle beam that reaches the sample 12 (radiated thereto) and the amount of secondary charged particles that reach the detector 13 (detected therefrom) are reduced. Therefore, the thickness of the diaphragm 19, that is, the thickness of the thin film 31, is desirably set to, for example, 5 to 50 nm.

Moreover, in the case when the sample 12 is observed in a non-vacuum state, such as under the atmospheric pressure, the primary charged particle beam and the secondary charged particles are scattered or absorbed between the diaphragm 19 and the sample 12, with the result that the amount of the primary charged particle beam radiated to the sample 12 and the amount of the secondary charged particles detected by the detector 13 are further reduced. For this reason, the thickness of the diaphragm 19 (thickness of the thin film 31) is desirably made further thinner, and desirably set to, for example, 20 nm or less. That is, the thickness of the diaphragm 19 (thickness of the thin film 31) is further desirably set, for example, to 5 to 20 nm.

Moreover, in the case when the diaphragm 19 is distorted, the primary charged particle beam and the secondary charged particles are scattered, with the result that the amount of the primary charged particle beam radiated to the sample 12 and the amount of the secondary charged particles detected by the detector 13 are further reduced. For this reason, as the diaphragm 19, that is, as the thin film 31, a film having a tensile stress from the holding substrate 30 is desirably used. As the film having such a tensile stress, a film, which is made of a material having a thermal expansion coefficient higher than the thermal expansion coefficient of the holding substrate 30 made of, for example, Si, is desirably used. Desirable examples of this material include nitrides of metal such as silicon nitride (SiN) or aluminum nitride (AlN), or polyimide.

As shown in FIG. 4, the plane shape of the diaphragm (film portion) 19, that is, the opening 32a of the through-hole 32, is desirably set to a regular square or a regular octagon. Thus, the stress applied to the diaphragm 19 can be evenly dispersed within the main surface 30a. In this case, however, as the area of the diaphragm 19 becomes larger, the diaphragm 19 tends to be easily damaged by a pressure difference between the inside and the outside of the vacuum chamber 4. In other words, as the area of the diaphragm 19 becomes larger, the pressure resistance property of the diaphragm 19 is lowered. Therefore, in the case when the length of a certain side needs to be made longer, the plane shape of the opening 32a of the through-hole 32 is formed into a rectangular shape so that by shortening the length of the adjacent sides, it is possible to prevent or suppress the diaphragm 19 from being damaged due to the pressure difference between the inside and the outside of the vacuum chamber 4.

In the case when, by using a Si substrate having a substrate orientation (100) as the holding substrate (base substrate) 30, the anisotropic etching process is carried out, the angle formed by the side face of the through-hole 32 relative to the main surface 30a (or the main surface 30b) of the holding substrate 30 is set to 54 to 55°. For this reason, the width dimension d1 of the diaphragm 19, that is, the width dimension d1 of the opening 32a of the through-hole 32, becomes smaller than a width dimension d2 of the opening portion 31a formed on the thin film 31 on the main surface 30b, that is, the width dimension d2 of the through-hole 32. In other words, the width dimension d2 of the through-hole 32 becomes larger than the width dimension d1 of the diaphragm 19.

On the other hand, in the case when an anisotropic etching process is carried out by using a Si substrate having a substrate orientation (110) as the holding substrate (base substrate) 30, the angle formed by the side face of the through-hole 32 relative to the main surface 30a (or the main surface 30b) of the holding substrate 30 is set to 90°. For this reason, since the width dimension d2 of the through-hole 32 becomes equal to the width dimension d1 of the diaphragm 19, it becomes possible to miniaturize the diaphragm element 18a.

On the main surface 30a of the holding substrate (base substrate) 30, a pattern 33a composed of a buffer film (film portion) 33 is formed at a region other than a region 30c on which the diaphragm (film portion) 19 is formed. On the main surface 30a of the holding substrate 30, the buffer film 33 is formed above the diaphragm 19 (thin film 31), that is, so as to be positioned on the sample 12 side rather than on the diaphragm 19 along the Z-axis direction (direction in which the primary charged particle beam is radiated). The buffer film 33 prevents the sample 12 held on the sample stage (holding unit) 22 from coming into contact with the diaphragm 19. In the example of FIG. 3, the buffer film 33 is formed on the thin film 31 above the main surface 30a.

In the case when the sample stage 22 is moved in the Z-axis direction so as to adjust the focal point with a high magnification, with the sample 12 having, for example, irregularities on its surface with the great maximum height, being held thereon, the diaphragm element 18a and the sample 12 tend to be easily made in contact with each other. However, in the first embodiment, on the main surface 30a of the holding substrate 30, the buffer film 33 is formed so as to be positioned on the sample 12 side (sample stage 22 side) rather on the diaphragm 19 along the Z-axis direction (direction in which the primary charged particle beam is radiated). For this reason, when the diaphragm element 18a and the sample 12 are made in contract with each other, it is possible to prevent the diaphragm 19 and the sample 12 from coming into contact with each other by allowing the buffer film 33 and the sample 12 to be made in contact with each other.

With respect to the film thickness of the buffer film (film portion) 33, although it also depends on the thickness of the sample 12, when the thickness of the sample 12 is thinner than, for example, 20 μm, the upper limit value of the film thickness may be set to, for example, 20 μm, with the lower limit value thereof being set to the thickness of the sample 12. Even in the case when the buffer film 33 is formed by using a method that is suitable for forming a film having a comparatively large film thickness, such as a coating method or the like, if the film thickness exceeds 20 μm, unevenness of film thickness and film quality occurs within the in-plane of the main surface 30a of the holding substrate 30, with the result that irregularities might occur on the surface of the buffer film 33.

As the buffer film (film portion) 33, examples of the desirable material include organic films, inorganic film or metal films. Among these, an optimal material may be selected depending on the thickness of a material to be observed, kinds of charged particles, limitations in the manufacturing process, etc. In the case when an organic film is used as the material for the buffer film 33, for example, polyimide may be used. The polyimide is easily processed, and superior in heat resistance and stability. Therefore, by using the polyimide as the material for the buffer film 33, it is possible to easily produce the buffer film 33 that is superior in heat resistance and stability.

The pattern 33a composed of the buffer film (film portion) 33 is formed on two regions that sandwich a region 30c in which the diaphragm (film portion) 19 is formed, of the main surface 30a of the holding substrate (base substrate) 30, when seen in a plan view. As shown in FIG. 4, for example, when the plane shape of the diaphragm 19 is a regular square, the pattern 33a composed of the buffer film 33 is desirably formed on at least outside regions of two sides that are opposed to each other of four sides on the outer periphery of the diaphragm 19. In other words, the pattern 33a composed of the buffer film 33 is desirably formed on at least two regions 30d and 30e that are positioned, with the region 30c in which the diaphragm 19 is formed being sandwiched therebetween, within the main surface 30a of the holding substrate 30, when seen in a plan view.

Thus, even when the buffer film 33 and the sample 12 are made in contact with each other, a force applied to the main surface 30a of the holding substrate 30 can be dispersed evenly to two regions 30d and 30e that are positioned, with the region 30c in which the diaphragm 19 is formed being sandwiched therebetween, when seen in a plan view. As a result, it is possible to further positively prevent the diaphragm 19 and the sample 12 from coming into contact with each other, without causing one of the diaphragm element 18a and the sample 12 to tilt relative to the other.

Moreover, a region between the region 30d and the region 30e, that is, the region from which the buffer film 33 is removed, is allowed to function as a flow passage FP through which a supplied gas flows when a gas lighter than air is supplied between the diaphragm element 18a and the sample 12 in a second embodiment to be described later. When seen in a plan view, this flow passage FP is desirably formed on the main surface 30a of the holding substrate 30 so as to pass through the region 30c in which the diaphragm 19 is formed, and cross the region from one side to the other side. Thus, upon supplying the gas lighter than air between the diaphragm element 18a and the sample 12, since the supplied gas is positively allowed to flow between the diaphragm 19 and the sample 12, it becomes possible to improve the S/N ratio of an image obtained by the charged particle beam device.

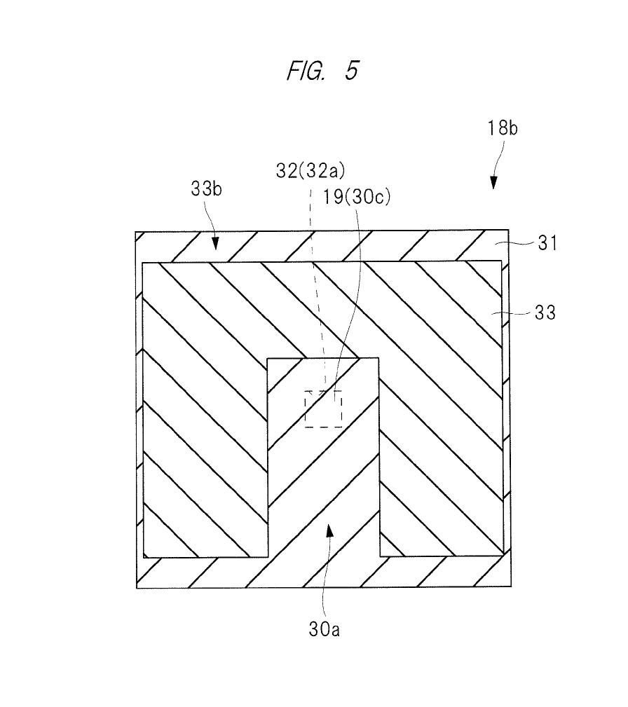

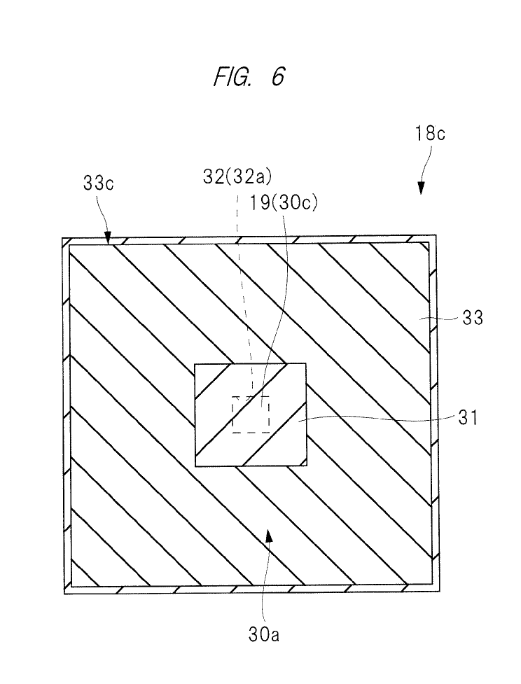

Additionally, the case in which the pattern composed of the buffer film 33 is formed at least two regions, with the region 30c in which the diaphragm 19 is formed being sandwiched therebetween, also includes a case in which the buffer films 33 are formed on a region including at least two regions, with the region 30c in which the diaphragm 19 is formed being sandwiched therebetween. Therefore, this case further includes a case in which the pattern composed of the buffer film 33 is integrally formed so on a region including at least two regions, with the region 30c in which the diaphragm 19 is formed being sandwiched therebetween. For example, as described later by reference to FIG. 5, this case further includes a case in which the pattern composed of the buffer film 33 is integrally formed in a manner so as to surround three sides of the region 30c in which the diaphragm 19 is formed, when seen in a plan view. Alternatively, as described later by reference to FIG. 6, this case still further includes a case in which the pattern composed of the buffer film 33 is integrally formed in a manner so as to surround four sides of the region 30c in which the diaphragm 19 is formed, when seen in a plan view.

The pattern 33a composed of the buffer film (film portion) 33 is formed at least on a region separated toward the peripheral edge side from the outer periphery of the opening 32a of the through-hole 32 on the main surface 30a, when seen in a plan view. That is, the pattern 33a composed of the buffer film 33 is formed at least on a region separated toward the peripheral edge side from the region 30c in which the diaphragm (film portion) 19 is formed. Thus, the pattern 33a made of the buffer film 33 is prevented from being overlapped with the opening 32a, that is, the diaphragm 19, when seen in a plan view, so that all the portions of the diaphragm 19 formed in a manner so as to cover the opening 32a make it possible to transmit or pass a charged particle beam therethrough.

Moreover, the pattern 33a composed of the buffer film (film portion) 33 is formed on a region separated toward the diaphragm (film portion) 19 side (the center side) by a predetermined width dimension d3 from the peripheral edge of the holding substrate (base substrate) 30, when seen in a plan view. With this configuration, when the diaphragm element 18a is subjected to a dicing process to be formed into individual pieces in the manufacturing process of the diaphragm element 18a, the buffer film 33 can be used as a positioning mark for use in positioning regions (scribing regions) to be subjected to the dicing process.

Therefore, when seen in a plan view, the pattern 33a composed of the buffer film (film portion) 33 is formed on regions 30d and 30e that are separated toward the peripheral edge side from the region 30c in which the diaphragm (film portion) 19 is formed, and also separated toward the center side by the predetermined width dimension d3 from the peripheral edge of the holding substrate (base substrate) 30.

The desirable range of the width dimension d3 depends on methods for dicing the diaphragm element 18a. In the case when the dicing process is carried out by a dicing device provided with a diamond rotary slicer (blade), since influences of cutting water need to be taken into consideration, the desirable range of the width dimension d3 is set to, for example, 50 to 500 μm. Moreover, in the case of using laser to carry out the dicing process, since damages caused on the diaphragm 19 are small, and since the process can be carried out while maintaining the smoothness on the peripheral edge of the diaphragm element 18a, that is, on the dicing surface, the width dimension d3 can be made smaller than that in the case of the dicing process using the dicing device. In the case of the dicing process by the use of laser, the desirable range of the width dimension d3 is set to, for example, 1 μm or more.

More desirably, as shown in FIG. 3, the pattern 33a composed of the buffer film (film portion) 33 is formed on a region separated toward the peripheral edge side by a predetermined width dimension d4 from the outer periphery of the opening portion 31a, that is, the periphery of the through-hole 32 of the thin film 31 on the main surface 30b. With this configuration, the buffer film 33 is prevented from being formed in a region overlapping with the opening portion 31a, that is, the through-hole 32, when seen in a plan view. That is, the buffer film 33 is prevented from being formed on a portion having a small strength, with the thickness of the holding substrate 30 becoming thinner by the formation of the through-hole 32 in the holding substrate 30. The width dimension d4 can be set to, for example, about 0 to 500 μm.

Additionally, the reason that the pattern 33a composed of the buffer film 33 is formed on a region separated toward the peripheral edge side from the outer periphery of the opening portion 31a is because a stress exerted by the buffer film 33 might give influences to the diaphragm 19. Therefore, in the case when the stress exerted by the buffer film 33 is extremely small, the pattern 33a composed of the buffer film 33 can also be formed on a region separated toward the peripheral edge side from the region 30c in which the diaphragm 19 is formed, corresponding to a portion inside the opening portion 31a, when seen in a plan view. In this case, the buffer film 33 can be formed in a region separated toward the peripheral edge side by, for example, 1 μm or more from the region 30c in which the diaphragm 19 is formed.

### First Modification Example to Third Modification Example of Diaphragm Element

FIGS. 5 to 7 are plan views of respective diaphragm elements of first to third modification examples of the first embodiment, when seen from the sample side. FIGS. 5 to 7 respectively show diaphragm elements 18b to 18d having different pattern shapes of the pattern composed of the buffer film 33, when seen in a plan view.

As shown in FIG. 5, in the diaphragm element (diaphragm member) 18b of the first modification example of the first embodiment, the plane shape of the diaphragm (film portion) 19 is a regular square, and a pattern 33b composed of the buffer film (film portion) 33 is formed on outside regions of three sides of the four sides of the outer periphery of the diaphragm 19, when seen in a plan view. Moreover, the pattern 33b composed of the buffer film 33 is integrally formed so as to surround the three sides of the region 30c in which the diaphragm 19 is formed, when seen in a plan view.

In the diaphragm element 18b shown in FIG. 5, of the four sides on the periphery of the diaphragm 19, the number of sides which the buffer film 33 is formed on the outside thereof is three, which is greater than the number of sides (two) which the buffer film 33 is formed on the outside thereof in the diaphragm elements 18a shown in FIG. 4. For this reason, the diaphragm element 18b positively makes it possible to prevent the diaphragm 19 and the sample 12 from coming into contact with each other when the sample 12 having irregularities on its surface is moved, in comparison with the case in which the diaphragm element 18a is used.

As shown in FIG. 6, in a diaphragm element (diaphragm member) 18c of a second modification example of the first embodiment, the plane shape of the diaphragm (film portion) 19 is a regular square, and the pattern 33c composed of the buffer film (film portion) 33 is formed on outside regions of all the four sides on the outer periphery of the diaphragm 19, when seen in a plan view. Moreover, the pattern 33c composed of the buffer film 33 is integrally formed so as to surround the four sides of the region 30c in which the diaphragm 19 is formed, when seen in a plan view.

In the diaphragm element 18c shown in FIG. 6, of the four sides on the outer periphery of the diaphragm 19, the number of the sides which the buffer film 33 is formed on the outside thereof is 4, which is greater than the number of sides (three) which the buffer film 33 is formed on the outside thereof in the diaphragm element 18b shown in FIG. 5. For this reason, the diaphragm element 18c makes it possible to more positively prevent the diaphragm 19 and the sample 12 from coming into contact with each other, when the sample 12 having irregularities on its surface is moved, in comparison with the case using the diaphragm element 18b.

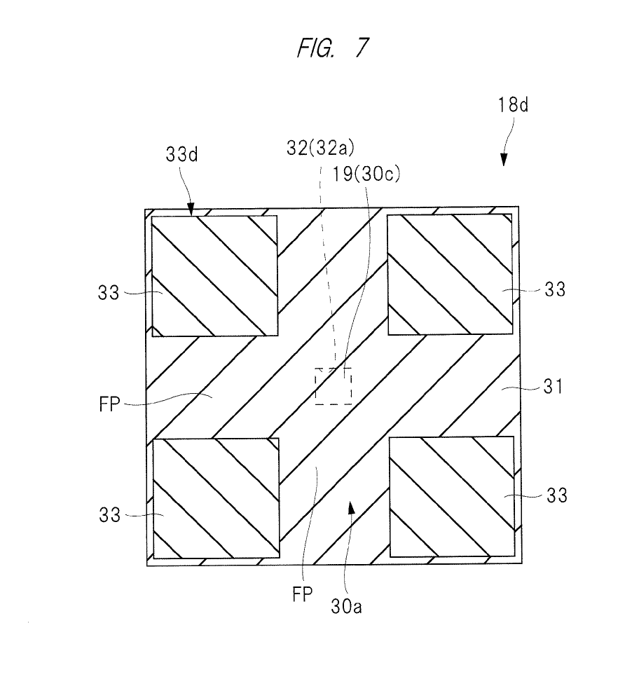

As shown in FIG. 7, in the diaphragm element (diaphragm member) 18d of a third modification example of the first embodiment, the plane shape of the diaphragm 19 is a regular square, and the pattern 33d composed of the buffer film (film portion) 33 is formed outside so as to be separated on four portions along a diagonal line direction, from the respective apexes of the diaphragm 19. Moreover, on the outside regions of any sides of the four sides on the outer periphery of the diaphragm 19, no buffer film 33 is formed. That is, in a region having a cross shape with which the regions 30c in which the diaphragm 19 is formed is intersected, the buffer film 33 is removed therefrom.

This region having the cross shape from which the buffer film 33 is removed is allowed to function as a flow passage FP through which a supplied gas flows when a gas lighter than air is supplied between the diaphragm element 18d and the sample 12, in a second embodiment to be described later. When seen in a plan view, this flow passage FP is desirably composed of two flow passages that are positioned on the main surface 30a so as to pass through the region 30c in which the diaphragm 19 is formed, and intersect with each other so as to be formed to cross the region from one side to the other side. Thus, upon supplying the gas lighter than air between the diaphragm element 18d and the sample 12, since the supplied gas is positively allowed to flow between the diaphragm 19 and the sample 12, it becomes possible to improve the S/N ratio of an image obtained by the charged particle beam device.

### Manufacturing Process of Diaphragm Elements

Next, one example of a manufacturing process of the diaphragm element (diaphragm member) in accordance with the first embodiment will be explained.

FIGS. 8 to 14 are cross-sectional views showing main parts in the manufacturing process of the diaphragm element of the first embodiment. Additionally, FIGS. 8 to 14 show cross sections corresponding to the aforementioned FIG. 3.

First, as shown in FIG. 8, a holding substrate (base substrate) 30 having a main surface 30a and a main surface 30b on the opposite side to the main surface 30a is prepared. As described earlier, as the holding substrate 30, for example, a Si substrate having, for example, a substrate orientation (100) or (110) may be used. Thus, as described later, by carrying out an anisotropic etching process using an etching liquid composed of an alkaline aqueous solution, the through-hole 32 (see FIG. 3) can be easily formed in the holding substrate 30. Moreover, a substrate whose two surfaces are finished into mirror surfaces may be used as the holding substrate 30. Thus, a machining process can be easily carried out on the two surfaces of the holding substrate 30.

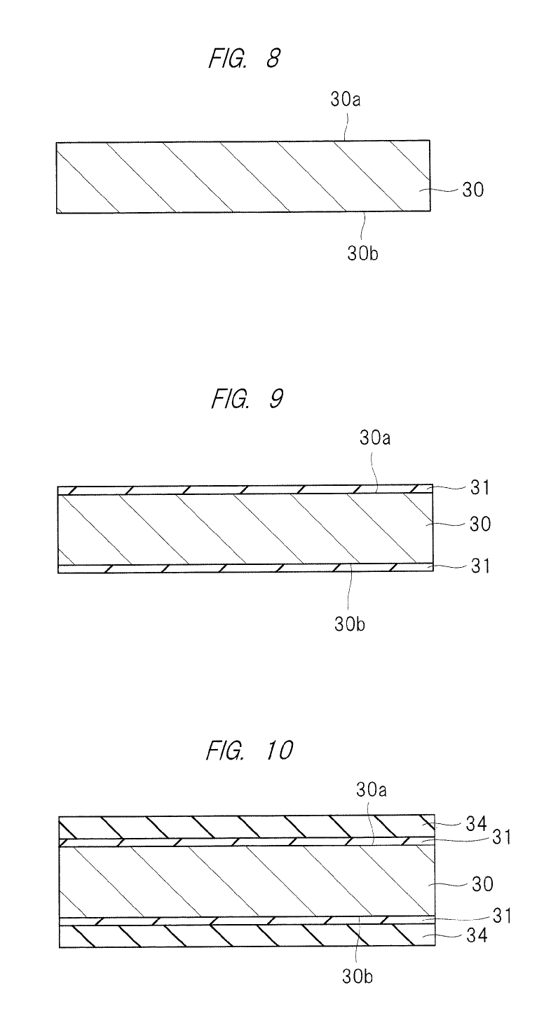

Additionally, in FIG. 8, only a region in which one diaphragm element is formed of the holding substrate 30 is illustrated; however, actually, the holding substrate 30 includes a region in which a plurality of diaphragm elements are formed along the direction in parallel with the main surface 30a or the main surface 30b (the same is true for FIGS. 9 to 14).

Next, as shown in FIG. 9, the thin film 31 is formed on each of the two surfaces of the holding substrate (base substrate) 30, that is, on the main surface 30a and the main surface 30b. For example, by carrying out a chemical vapor deposition method (CVD method) at a temperature of 700° C., a SiN film may be formed as the thin film 31.

Additionally, as described earlier, the thickness of the thin film 31 is desirably set to, for example, 5 to 50 nm, more desirably, for example, 5 to 20 nm. Moreover, as described earlier, a film having a tensile stress is desirably used as the thin film 31, and for example, the desirable materials therefor include nitrides of metal, such as SiN and AIN, or polyimide.

Furthermore, in order to improve the pressure resistance property of the diaphragm (membrane, film portion) 19 formed by processes as described later, after the formation of the thin film 31, a heating treatment is desirably carried out at a temperature that exceeds the temperature at the time of forming the thin film 31. By this heating treatment, the diaphragm 19 is sintered to have an increased density with an improved rigidity, so that the pressure resistant property of the diaphragm 19 is improved. For example, in the case when the thin film 31 is made of SiN, the temperature of the heating treatment is desirably set to 800° C. or more.

Next, as shown in FIG. 10, an insulating film 34 is formed on each of the two surfaces of the holding substrate (base substrate) 30 with the thin films 31 formed on the two surfaces, that is, on the main surface 30a and the main surface 30b. By forming the insulating film 34, during a period before the formation of the diaphragm 19 by using processes as described later, the thin film 31 can be protected, and it is possible to prevent or suppress the thin film 31 from being scratched. For example, by using a CVD method, a silicon oxide (SiO₂) film may be formed as the insulating film 34.

At this time, of the two surfaces of the holding substrate 30, the insulating film 34 may be formed only on the main surface 30a on which the diaphragm 19 is formed. However, desirably, as shown in FIG. 10, the insulating films 34 are formed on the two surfaces of the main surface 30a and the main surface 30b of the holding substrate 30. By forming the insulating film 34 not only on the main surface 30a, but also on the main surface 30b, it becomes possible to prevent or suppress the thin film 31 serving as a mask when the holding substrate 30 is removed from the main surface 30b by etching, from being scratched.

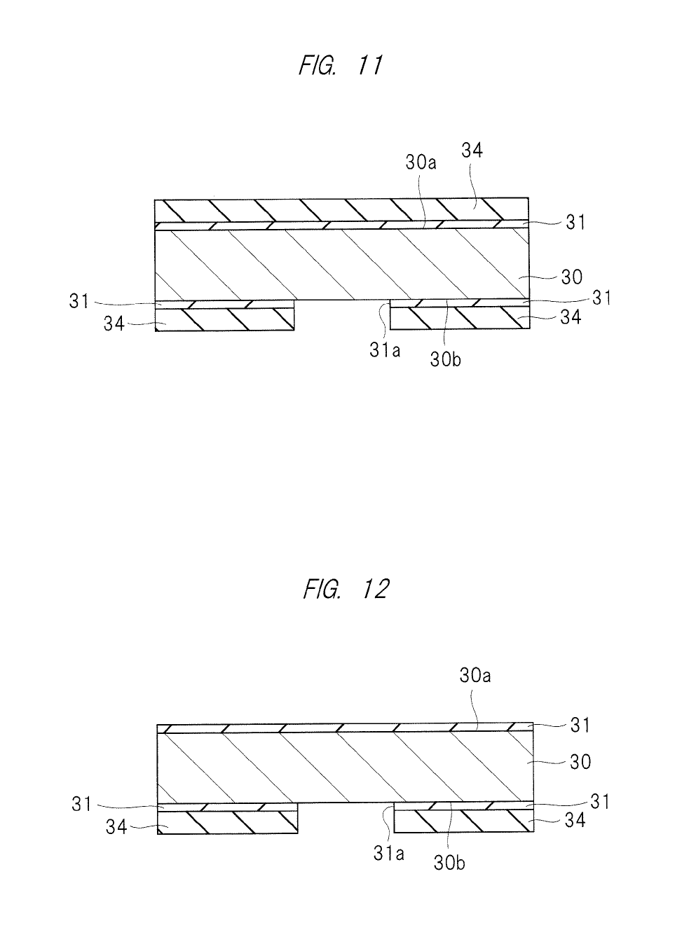

Next, as shown in FIG. 11, on the main surface 30b of the holding substrate (base substrate) 30, an opening portion 31a is formed on each of the insulating film 34 and the thin film 31. On a region of the main surface 30b of the holding substrate 30 in which a through-hole 32 (see FIG. 3) is formed, for example, by using a photolithography technique and etching, the insulating film 34 and the thin film 31 are removed. Thus, the opening portion 31a that penetrates the insulating film 34 and the thin film 31 to reach the holding substrate 30 is formed. In the opening portion 31a, the holding substrate 30 is exposed.

Next, as shown in FIG. 12, the insulating film 34 is removed from the main surface 30a of the holding substrate (base substrate) 30. Thus, on the main surface 30a of the holding substrate 30, the thin film 31 is exposed to the surface.

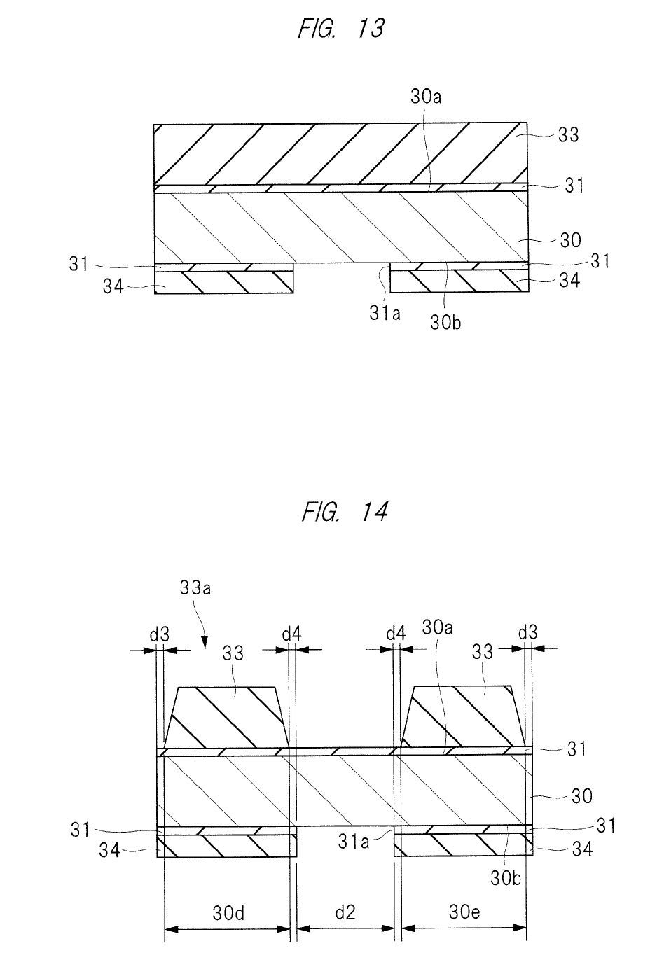

Next, as shown in FIG. 13, a buffer film (film portion) 33 is formed on the main surface 30a of the holding substrate (base substrate) 30. As descried earlier, a film made of an organic film, an inorganic film or a metal film may be formed as the buffer film 33, and for example, polyimide may be used as the material for the organic film. Moreover, with respect to the film thickness of the buffer film 33, although it also depends on the thickness of the sample 12, when the thickness of the sample 12 is thinner than, for example, 20 μm, the upper limit value of the film thickness may be set to, for example, 20 μm, with the lower limit value thereof being set to the thickness of the sample.

Next, as shown in FIG. 14, one portion of the buffer film (film portion) 33 is removed by a photolithography technique and etching so that a pattern 33a composed of the buffer film 33 is formed.

The pattern 33a composed of the buffer film 33 is formed on a region separated toward the diaphragm 19 side (the center side) by the predetermined width dimension d3 from the peripheral edge of the holding substrate (base substrate) 30, when seen in a plan view. With this configuration, when the diaphragm element 18a is subjected to a dicing process to be formed into individual pieces in a process to be carried out later, the buffer film 33 can be used as a positioning mark for use in positioning scribing regions.

Moreover, the pattern 33a composed of the buffer film 33 is formed on a region separated toward the peripheral edge side by the predetermined width dimension d4 from the outer periphery of the opening portion 31a. With this configuration, the buffer film 33 is prevented from being formed in a region overlapping with the opening portion 31a, that is, the through-hole 32, when seen in a plan view. That is, the buffer film 33 is prevented from being formed on a portion having a small strength, with the thickness of the holding substrate 30 becoming thinner by the formation of the through-hole 32 in the holding substrate 30. The width dimension d4 can be set to, for example, about 0 to 500 μm.

Additionally, after the formation of the pattern 33a, a resin film (the illustration thereof is omitted) may be applied thereto so as to cover the entire surface of the holding substrate 30.

Next, a through-hole 32 (see FIG. 3) is formed on the holding substrate (base substrate) 30. On the main surface 30b of the holding substrate 30, an anisotropic etching process using an etching solution made of an alkaline aqueous solution is carried out, with the thin film 31 in which the opening portion 31a is formed being used as a mask, so that the holding substrate 30 exposed to the opening portion 31a is removed (etched). Thus, the through-hole 32 (see FIG. 3) that reaches the main surface 30a from the main surface 30b is formed on the holding substrate 30.

In the case when, for example, a Si substrate is used as the holding substrate 30, an etching solution composed of an alkaline aqueous solution, such as a potassium hydroxide (KOH) aqueous solution or a tetra-methyl-ammonium-hydroxide (TMAH) aqueous solution, may be used.

In this manner, by forming the through-hole 32 (see FIG. 3) that reaches the main surface 30a from the main surface 30b on the holding substrate 30, the diaphragm 19 made of the thin film 31 remaining in a manner so as to cover the opening 32a (see FIG. 3) of the through-hole 32 is formed on the main surface 30a. Thereafter, in the scribing region, by carrying out a dicing process on the holding substrate 30 to be formed into individual pieces, the diaphragm element 18a as shown in FIG. 3 is formed. Additionally, in the case when upon attaching the diaphragm element 18a to an attachment to be described later, the holding substrate 30 is too thick, prior to the dicing process, the main surface 30b may be thinned by using a back grinding method or the like so as to adjust the height. In this case, the main surface 30b has a structure to which the holding substrate 30 is exposed.

Moreover, when the entire surface of the holding substrate 30 is covered with a resin film (the illustration thereof is omitted), the resin film (the illustration thereof is omitted) positioned on the diaphragm 19 and the buffer film 33 is removed.

Additionally, in the case when prior to the formation of the through-hole 32 (see FIG. 3), the insulating film 34 is formed on the main surface 30b as shown in FIG. 14, the insulating film 34 is removed by using an etching solution, such as hydrofluoric acid (HF), before the formation of the through-hole 32 or after the formation of the through-hole 32.

In the case when an anisotropic etching process is carried out by using a Si substrate having a substrate orientation (100) or (110) as the holding substrate (base substrate) 30, since the side face of the through-hole 32 to be formed corresponds to a (111) plane, the through-hole 32 can be formed with a good shape accuracy.

As described earlier, in the case of using a Si substrate having a substrate orientation (100) as the holding substrate 30, the angle made by the side face of the through-hole 32 relative to the main surface 30a (or the main surface 30b) of the holding substrate 30 is set to 54 to 55°. For this reason, the width dimension d1 (see FIG. 3) of the diaphragm (film portion) 19, that is, the width dimension d1 of the opening 32a of the through-hole 32, becomes smaller than the opening portion 31a formed on the thin film 31 on the main surface 30b, that is, the width dimension d2 of the through-hole 32. In other words, the width dimension d2 of the through-hole 32 becomes larger than the width dimension d1 of the diaphragm 19.

On the other hand, in the case when a Si substrate having a substrate orientation (110) is used as the holding substrate 30, the angle formed by the side face of the through-hole 32 relative to the main surface 30a (or the main surface 30b) of the holding substrate 30 is set to 90°. For this reason, since the width dimension d2 of the through-hole 32 becomes equal to the width dimension d1 of the diaphragm (film portion) 19, it becomes possible to miniaturize the diaphragm element 18a.

Additionally, the reason that the pattern 33a composed of the buffer film (film portion) 33 is formed on a region separated toward the peripheral edge side from the outer periphery of the opening portion 31a is because a stress exerted by the buffer film 33 might give influences to the diaphragm 19. Therefore, in the case when the stress exerted by the buffer film 33 is extremely small, the pattern 33a composed of the buffer film, 33 can also be formed on a region separated toward the peripheral edge side from the region 30c (see FIG. 4) in which the diaphragm 19 is formed, corresponding to a portion inside the opening portion 31a, when seen in a plan view. In this case, the buffer film 33 can be formed in a region separated toward the peripheral edge side by, for example, 1 μm or more from the region 30c in which the diaphragm 19 is formed.

### Fourth Modification Example of Diaphragm Element

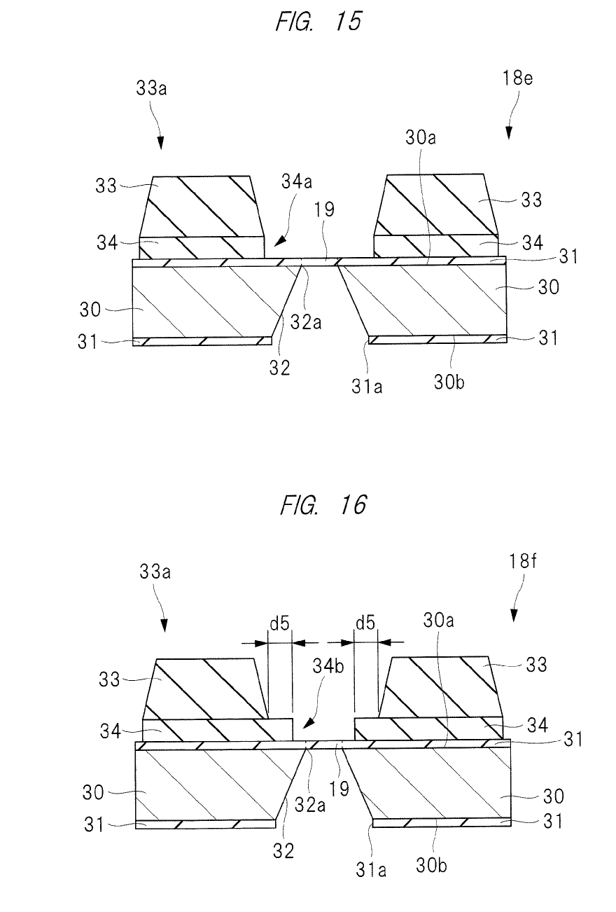

FIG. 15 is a cross-sectional view showing main parts of a diaphragm element in accordance with a fourth modification example of the first embodiment.

As shown in FIG. 3, in the diaphragm element 18a of the first embodiment, the buffer film 33 is directly formed on the thin film 31 of the main surface 30a of the holding substrate 30. On the other hand, as shown in FIG. 15, in a diaphragm element (diaphragm member) 18e of a fourth modification example of the first embodiment, on the main surface 30a of the holding substrate (base substrate) 30, the buffer film (film portion) 33 is formed on the thin film 31 through the insulating film 34. That is, the pattern 33a composed of the buffer film 33 is formed on the thin film 31 through the pattern 34a composed of the insulating film 34. The pattern 34a composed of the insulating film 34 is the same as the pattern 33a composed of the buffer film 33, when seen in a plan view.

For example, in the case when the buffer film 33 made of an organic film such as polyimide, an inorganic film or a metal film, is directly formed on the thin film 31 made of, for example, SiN, the bonding property (adhesive strength) between the buffer film 33 and the thin film 31 sometimes becomes weak. On the other hand, in the case when the buffer film 33 made of an organic film such as polyimide, an inorganic film or a metal film, is formed on the thin film 31 made of, for example, SiN, through the insulating film 34 made of, for example, SiO₂ or the like, it becomes possible to improve the bonding property (adhesive strength) between the buffer film 33 and the thin film 31.

In the manufacturing process of the diaphragm element 18a of the first embodiment, after the formation of the opening portion 31a as shown in FIG. 11, the insulating film 34 is removed from the main surface 30a of the holding substrate 30, as shown in FIG. 12.

On the other hand, in the manufacturing process of a diaphragm element 18e in accordance with a fourth modification example of the first embodiment, after the formation of the opening portion 31a as shown in FIG. 11, without removing the insulating film 34 from the main surface 30a of the holding substrate 30, the buffer film 33 is formed on the main surface 30a of the holding substrate 30. Then, a portion of the buffer film 33 is removed by the photolithography technique and etching so that after the pattern 33a made of the buffer film 33 is formed, the insulating film 34 is removed from a region in which no pattern 33a is formed; thus, a pattern 34a made of the insulating film 34 is formed.

Thereafter, by using the same manufacturing process as that of the diaphragm element 18a of the first embodiment, for example, a resin film (illustration thereof is omitted) is formed, and by carrying out an anisotropic etching process, the holding substrate 30 exposed to the opening portion 31a is removed (etched) so that the through-hole 32 is formed. Thus, the diaphragm element 18e shown in FIG. 15 is formed.

### Fifth Modification Example of Diaphragm Element

FIG. 16 is a cross-sectional view showing main parts of a diaphragm element in accordance with a fifth modification example of the first embodiment.

As shown in FIG. 15, in the diaphragm element 18e of the fourth modification example of the first embodiment, the pattern 34a composed of the insulating film 34 is the same as the pattern 33a composed of the buffer film 33, when seen in a plan view.

On the other hand, in a diaphragm element (diaphragm member) 18f of the fifth modification example of the first embodiment, as shown in FIG. 16, a pattern 34b composed of the insulating film 34 is formed so as to extend to a region on the diaphragm 19 side (center side) by a width dimension d5 from the region in which the pattern 33a made of the buffer film 33 is formed. Additionally, the region in which the above-mentioned pattern 34b is formed is separated toward the peripheral edge side from the region 30c (see FIG. 4) in which the diaphragm (film portion) 19 is formed, and is also included in a region separated toward the center side from the peripheral edge of the holding substrate (base substrate) 30.

By using this configuration, the region in which the insulating film 34 is formed is expanded toward the diaphragm 19 side (center side) in comparison with the diaphragm element 18e in the fourth modification example of the first embodiment. Moreover, in addition to the buffer film 33, the insulating film 34 formed in the expanded region also prevents the diaphragm 19 and the sample from coming into contact with each other. Therefore, the diaphragm element 18f makes it possible to further improve the function for preventing the diaphragm 19 and the sample 12 from coming into contact with each other in comparison with the diaphragm element 18e.

### Sixth Modification Example of Diaphragm Element

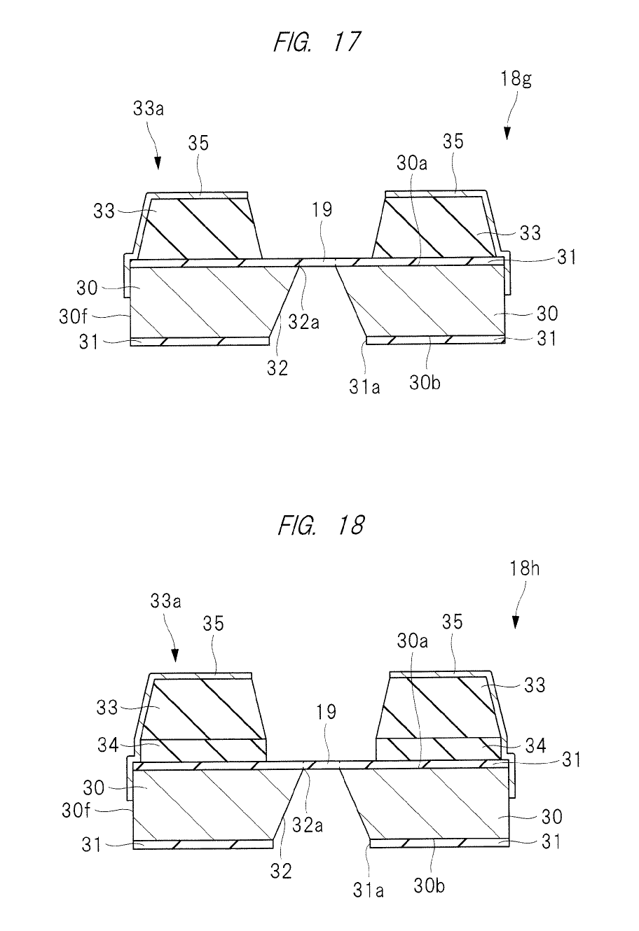

FIG. 17 is a cross-sectional view showing main parts of a diaphragm element in accordance with a sixth modification example of the first embodiment.

As shown in FIG. 17, a diaphragm element (diaphragm member) 18g of the sixth modification example of the first embodiment has a configuration in which in the diaphragm element (diaphragm member) 18a of the first embodiment, a sealing film (film portion) 35 made of a conductive film is formed on the pattern 33a made of the buffer film (film portion) 33. In other words, the sealing film 35 composed of the conductive film is formed on the surface of the pattern 33a composed of the buffer film 33. By using this configuration, it is possible to prevent secondary charged particles discharged from the sample 12 from being accumulated on the buffer film 33 or the diaphragm 19, and consequently to prevent the sensitivity of the detector 13 for detecting the secondary charged particles from being lowered. In other words, it becomes possible to prevent the reduction in the sensitivity caused by the accumulation of secondary charged particles on the buffer film 33 or the diaphragm 19.

Moreover, the sealing film 35 may also be formed on a side face 30f of the holding substrate (base substrate) 30. That is, the sealing film 35 is integrally formed on the surface of the pattern 33a composed of the buffer film 33 and the side face 30f of the holding substrate 30. Thus, as described later in a second embodiment, it becomes possible to further prevent the sensitivity reduction caused by the accumulation of secondary charged particles on the buffer film 33 or the diaphragm 19. Moreover, in the case when no sealing film 35 is formed on the side face 30f, by using a silver paste or a conductive seal so as to allow the frame 3 and the sealing film 35 to conduct to each other, it becomes possible to prevent secondary charged particles from being accumulated on the buffer film 33 and the diaphragm 19.

As the sealing film 35, a conductive film made of metal, such as aluminum (Al), copper (Cu), tungsten (W), titanium (Ti), tantalum (Ta), chromium (Cr), nickel (Ni), or molybdenum (Mo), may be used. Alternatively, as the sealing film 35, a conductive film made of a metal nitride, such as tungsten nitride (WN) or titanium nitride (TiN), or a metal compound, such as tungsten silicide (WSi) or nickel silicide (NiSi), may be used.

In a manufacturing process of the diaphragm element 18g in accordance with the sixth modification example of the first embodiment, after the production of the diaphragm element 18a of the first embodiment, in a state where a shielding plate is disposed so as to mask the diaphragm 19, by carrying out, for example, a sputtering method or a vapor deposition method, the sealing film 35 made of a conductive film is formed.

### Seventh Modification Example of Diaphragm Element

FIG. 18 is a cross-sectional view showing main parts of a diaphragm element in accordance with a seventh modification example in accordance with the first embodiment.

As shown in FIG. 18, a diaphragm element (diaphragm member) 18h of the seventh modification example of the first embodiment has a configuration in which in the diaphragm element (diaphragm member) 18e of the fourth modification example of the first embodiment, a sealing film (film portion) 35 made of a conductive film is formed on the pattern 33a made of the buffer film (film portion) 33. In other words, the sealing film 35 made of the conductive film is formed on the surface of the pattern 33a composed of the buffer film 33. By using this configuration, in the same manner as in the diaphragm element 18e of the fourth modification example of the first embodiment, it becomes possible to improve the bonding property (adhesive strength) between the buffer film 33 and the thin film 31. Moreover, in the same manner as in the diaphragm element 18g of the sixth modification example of the first embodiment, this configuration makes it possible to prevent the reduction in the sensitivity for detecting secondary charged particles.

Moreover, in the same manner as in the sixth modification example of the first embodiment, the sealing film 35 may also be formed on the side face 30f of the holding substrate (base substrate) 30.

In the same manner as in the sixth modification example of the first embodiment, as the sealing film 35, a conductive film made of metal, such as Al, Cu, W, Ti, Ta, Cr, Ni, or Mo, may be used. Alternatively, as the sealing film 35, in the same manner as in the sixth modification example of the first embodiment, a conductive film made of a metal nitride such as WN or TiN, or a metal compound such as WSi or NiSi, may be used.

In a manufacturing process of the diaphragm element 18h in accordance with the seventh modification example of the first embodiment, after the production of the diaphragm element 18e of the fourth modification example of the first embodiment, in a state where a shielding plate is disposed so as to mask the diaphragm. 19, by carrying out, for example, a sputtering method or a vapor deposition method, the sealing film 35 made of a conductive film may be formed.

Additionally, in place of the diaphragm element (diaphragm member) 18e of the fourth modification example of the first embodiment, by using the diaphragm element (diaphragm member) 18f of the fifth modification example of the first embodiment, a sealing film 35 made of a conductive film may be formed on the pattern 33a made of the buffer film 33.

### Observing Process by Charged Particle Beam Device

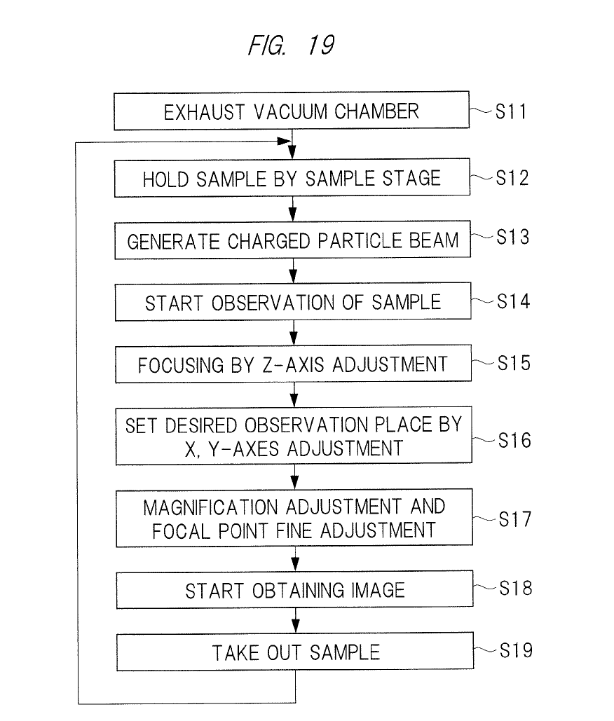

Next, an observing process by the charged particle beam device of the first embodiment will be explained. FIG. 19 is a flowchart showing parts of an observing process of the charged particle beam device in accordance with the first embodiment.

First, the vacuum chamber 4 is exhausted (step S11). In this step S11, for example, by the vacuum pump (exhaust unit) 6 controlled by the control unit 15, the vacuum chamber 4 partitioned by the charged particle optical lens barrel 2 and the frame 3 is exhausted through the vacuum pipe 7, so that the pressure inside the vacuum chamber 4 is reduced to vacuum. Therefore, the vacuum chamber 4 is maintained in a state in which the pressure inside the vacuum chamber 4 is reduced more than the pressure outside the vacuum chamber 4, that is, in a state in which there is a pressure deference between the inside of the vacuum chamber 4 and the outside thereof.

Next, the sample 12 is held by the sample stage (holding unit) (step S12). In this step S12, the sample 12 is mounted on the sample stage 22 to be held thereon. Moreover, in order to prevent the sample stage (holding unit) 22 or the sample 12 held on the sample stage 22 from coming into contact with the diaphragm element (diaphragm member) 18a, the height position of the sample stage 22 in the Z-axis direction is preliminarily lowered sufficiently by the Z-axis driving unit 24 controlled by, for example, the control unit 15.

Next, a charged particle beam is generated (step S13). In this step S13, the charged particle beam is generated by using, for example, a charged particle source 9 composed of an electron gun including filaments.

Next, an observation of the sample 12 is started (step S14). In this step S14, by adjusting conditions or the like of the optical lens 11 of the charged particle optical system 10 and displaying an image of the sample 12 on the personal computer 16, the observation is started. Additionally, at first, the magnification is set to a low level so as to smoothly carry out the next focusing process.

Next, a focusing process is carried out by the Z-axis adjustment (step S15). In this step S15, the height position of the sample 12 is gradually raised by using the Z-axis driving unit 24, while observing the image of the sample 12, and the focal point is adjusted so as to observe the sample 12 clearly.

Next, a desired observation place is set by X, Y-axes adjustment (step S16). In this step S16, the sample 12 is moved to a desired observation place by using the X, Y-axes driving unit 25, while observing the image of the sample 12.

Next, magnification adjustment and focal point fine adjustment are carried out (step S17). In this step S17, the adjustment of the magnification and fine adjustments of the Z-axis driving unit 24 are carried out.

Next, an image obtaining process is started (step S18). In this step S18, a switch for obtaining an image is pressed, so that the image is obtained by the personal computer 16, and the obtained image is stored. Then, by repeating these operations a plurality of times, desired observing processes are carried out on the sample 12, so that the resulting images are obtained.

Next, the sample 12 is taken out (step S19). In this step S19, after completion of the observation, the height position of the sample 12 is lowered by using the Z-axis driving unit 24, and after the sample 12 is kept away from the diaphragm element 18a, the sample 12 is taken out from the sample stage (holding unit) 22. Moreover, in the case when the next sample is observed, the operations from step S12 to step S19 are repeatedly carried out on the next sample.

Additionally, the flowchart of the observing process shown in FIG. 19 shows one example of operations of the charged particle beam device, and the order of the respective processes is not limited by the order shown in FIG. 19. Therefore, the order of the respective processes of step S11 to step S19 can be altered appropriately.

### Concerning Breakage of Diaphragm

For example, in a SEM having the same configuration as that of the SEM described in the aforementioned Patent Document 1, the sample is mounted on the diaphragm. In this case, since the diaphragm is thin, it is difficult to enlarge the area of the diaphragm, with the result that the range in which the sample can be observed is limited to a region on which the diaphragm is formed. Therefore, it is necessary to remount the sample on the diaphragm many times until a portion to be desirably observed has been mounted on the diaphragm. Moreover, since the diaphragm is thin, the diaphragm might be damaged upon exchanging samples or upon remounting the sample on the diaphragm. When the diaphragm is damaged, the sample or the atmospheric air enters the charged particle optical lens barrel disposed below, with the result that a failure might occur in the charged particle source.

On the other hand, in the case of a SEM having the same configuration as that of the SEM described in the aforementioned Patent Document 2, since this configuration is different from a configuration in which the sample is mounted on the diaphragm and maintained thereon, there is less possibility of the damaged diaphragm caused by the holding state of the sample. Moreover, since the sample can be moved onto the diaphragm element, it is not necessary to remount the sample on the diaphragm many times.

However, upon observing the sample with a high resolution, for adjusting a focal point at a high magnification, the sample stage needs to be moved so as to allow the sample held on the sample stage to come close to the diaphragm element. Upon allowing the sample to come close to the diaphragm element, for example, a user carries out the corresponding operation while paying attention so as not to make the diaphragm and the sample in contact with each other, by moving the sample stage while observing the image. However, since the sample sometimes needs to be brought to a distance as close as several tens of μms from the diaphragm, the diaphragm and the sample tend to be easily made in contact with each other, even when the user carries out the operation while paying attention as much as possible, with the result that the diaphragm is easily damaged.

Moreover, upon attaching the diaphragm element to the charged particle beam device, or upon exchanging the diaphragm elements, the diaphragm element falls on another member or comes close to another member, with the result that the diaphragm and another member are easily made in contact with each other to cause damages to the diaphragm.

In particular, in the case when the space in which the sample is disposed is maintained in a non-vacuum state, such as under the atmospheric pressure, and if the pressure inside the space in which the sample is disposed is higher than the pressure of the vacuum chamber, the focal point distance fluctuates by a composition of a gas positioned between the diaphragm element and the sample or a change of pressure. In other words, in the case when the pressure outside the vacuum chamber is higher than the pressure inside the vacuum chamber, with a pressure difference being present between the inside and the outside of the vacuum chamber, the focal point distance tends to easily fluctuate. For this reason, each time an observed image is captured, the distance between the diaphragm element and the sample needs to be adjusted, with the result that the diaphragm and the sample are more easily made in contact with each other to more easily cause damages to the diaphragm.

As described earlier, in the aforementioned Patent Document 2, a technique is disclosed in which in a SEM for observing an object in a non-vacuum environment, in the STEM mode, by using a spacer which is disposed on the periphery of an aperture and whose the height determines the operation distance, a controlling process is carried out so as to obtain the maximum resolution.

However, the technique disclosed in the aforementioned Patent Document 2 relates to a measuring method in which the STEM mode for detecting an electron beam transmitting the sample is used, and by making the sample and a spacer in contact with each other, the operation distance is determined by the height of the spacer, so that the maximum resolution can be achieved. Moreover, in the SEM disclosed in Patent Document 2, the spacer disposed on the periphery of the aperture is used for maintaining the distance between the diaphragm and the sample at a constant value, and is not used for preventing the diaphragm and the sample from coming into contact with each other.

Therefore, in the case when each time an observed image is captured, if the distance between the diaphragm and the sample needs to be adjusted, by the method described in Patent Document 2 in which the distance between the diaphragm and the sample is determined by using the spacer having a fixed height, it is not possible to prevent the diaphragm and the sample from coming into contact with each other.

In this manner, in the case when the diaphragm and the sample are easily made in contact with each other, the diaphragm tends to be easily damaged, thereby failing to capture an observed image stably with a high resolution. Therefore, the performance of the charged particle beam device is lowered.

### Main Characteristics and Effects of Present Embodiment

On the other hand, in accordance with the charged particle beam device 1 of the first embodiment, in the diaphragm element 18a, the diaphragm 19, which air-tightly separates the inside and the outside of the vacuum chamber 4 from each other in a state that the pressure inside the vacuum chamber 4 is reduced more than the pressure outside the vacuum chamber 4, and allows a charged particle beam to be transmitted therethrough, is formed. Moreover, in the diaphragm element 18a, the buffer film (film portion) 33, which prevents the sample 12 held on the sample stage (holding unit) 22 and the diaphragm 19 from coming into contact with each other, is formed along the Z-axis direction so as to be positioned on the sample 12 side (the sample stage 22 side) rather than on the diaphragm 19.

In this manner, since the buffer film 33 is formed in the diaphragm element 18a, the buffer film 33 and the sample 12 are made in contact with each other, when the sample 12 comes close to the diaphragm element 18a. For this reason, it is possible to prevent the diaphragm 19 and the sample 12 from coming into contact with each other and consequently to prevent the diaphragm 19 from being damaged. Therefore, since an observed image can be captured stably with a high resolution, the performance of the charged particle beam device can be improved.

Moreover, upon attaching the diaphragm element 18a to the charged particle beam device, or upon exchanging the diaphragm elements 18a, the diaphragm element 18a falls on another member, or comes close to another member, with the result that the buffer film 33 is made in contact with another member. Therefore, it is possible to prevent the diaphragm 19 and another member from coming into contact with each other and consequently to prevent the diaphragm 19 from being damaged.

In particular, in the case when the space in which the sample 12 is disposed is maintained in a non-vacuum state, such as under the atmospheric pressure, if the pressure inside the space in which the sample 12 is disposed is higher than the pressure of the vacuum chamber 4, the focal point distance fluctuates by a composition of a gas positioned between the diaphragm element 18a and the sample 12 or a change of pressure. In other words, in the case when the pressure outside the vacuum chamber 4 is higher than the pressure inside the vacuum chamber 4, with a pressure difference being present between the inside and the outside of the vacuum chamber 4, the focal point distance tends to easily fluctuate. For this reason, each time an observed image is captured, the distance between the diaphragm element 18a and the sample 12 needs to be adjusted.

In this case, it is not possible to prevent the diaphragm and the sample from coming into contact with each other, by using the method disclosed in Patent Document 2 for determining the distance between the diaphragm and the sample by the spacer having a fixed height. However, by using the diaphragm element 18a of the first embodiment, the effect for preventing the diaphragm 19 and the sample 12 from coming into contact with each other can be improved.

### Second Embodiment

Next, a charged particle beam device in accordance with a second embodiment of the present invention will be explained. In the charged particle beam device of the second embodiment, the diaphragm element (diaphragm member) includes an attachment to which a holding substrate (base substrate) is attached, and the attachment to which the holding substrate is attached is attached to the lower surface portion of the frame. Therefore, of the charged particle beam device of the second embodiment, those parts other than the attachment are the same as those of the charged particle beam device of the first embodiment, and the descriptions thereof will be omitted. Moreover, with respect to effects obtained by those parts other than the attachment of the charged particle beam device of the second embodiment, the same effects as those obtained by the charged particle beam device of the first embodiment are obtained, and the description thereof will be omitted.

Additionally, the following explanation will be given by exemplifying the diaphragm element (diaphragm member) 18h of the seventh modification example of the first embodiment shown in FIG. 18, as the diaphragm element. However, in place of the diaphragm element 18h, the diaphragm element 18a of the first embodiment, as well as the diaphragm elements 18b to 18g of the first modification example to sixth modification example of the first embodiment may be used.

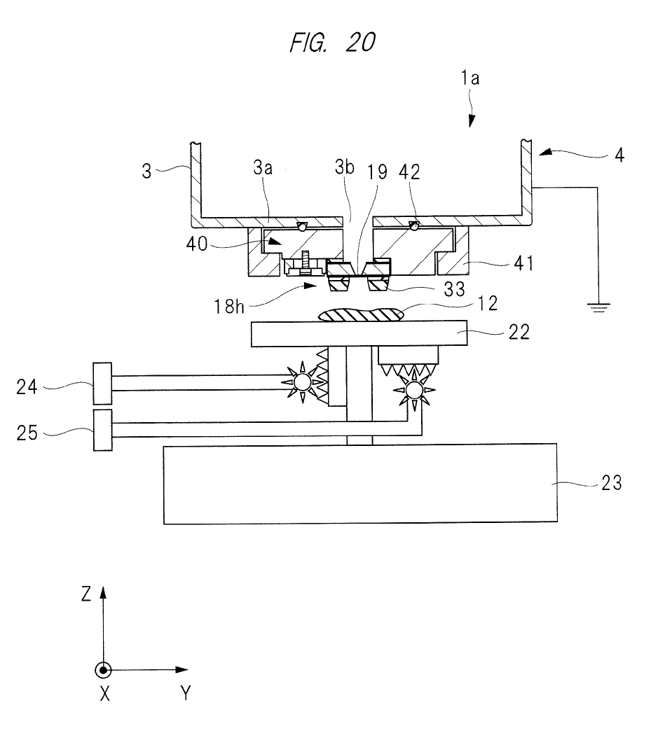

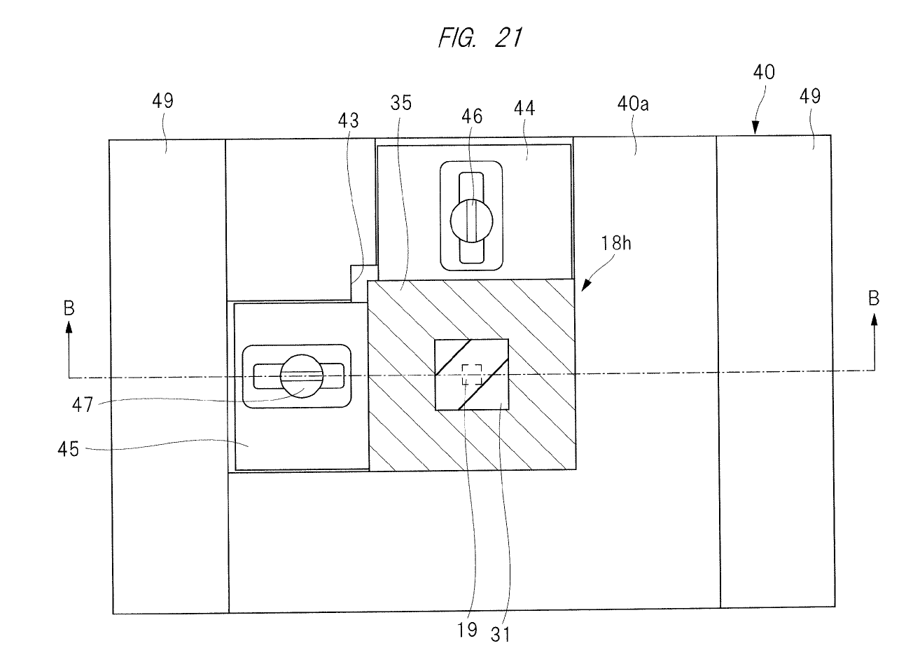

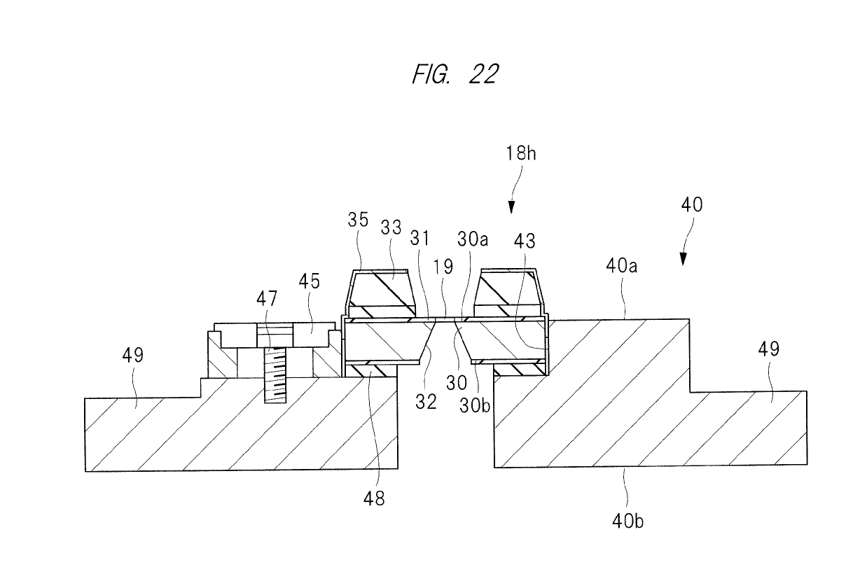

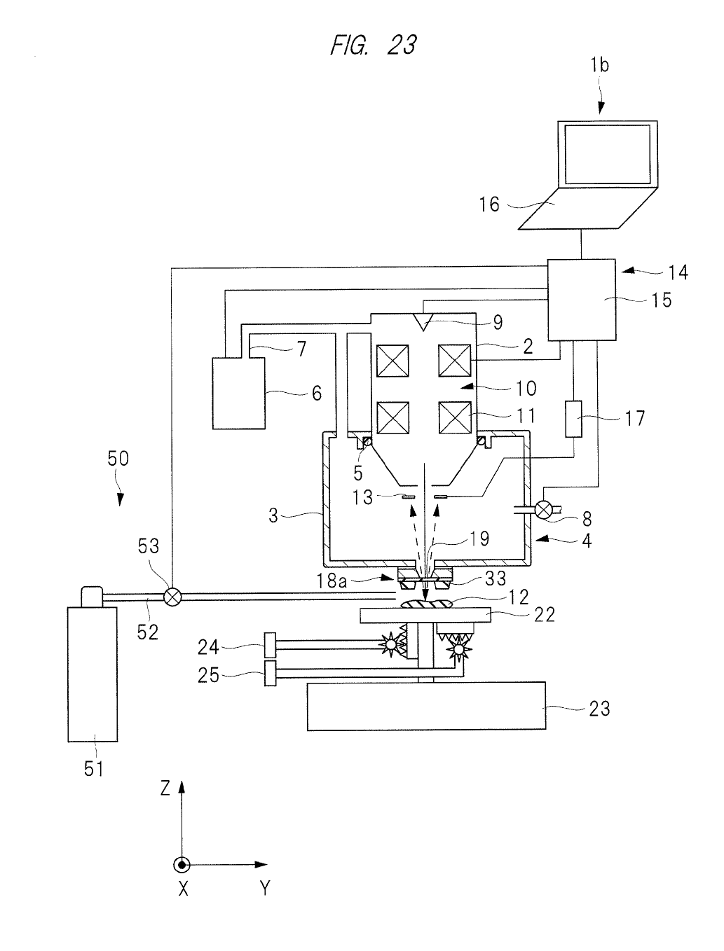

FIG. 20 is a view showing a configuration on the periphery of the diaphragm element and the sample stage of the charged particle beam device in accordance with the second embodiment. FIG. 21 is a plan view showing the attachment in accordance with the second embodiment, when seen from the sample side. FIG. 22 is a cross-sectional view showing main parts taken along the line B-B of FIG. 21.

As shown in FIGS. 20 to 22, in the charged particle beam device 1a of the second embodiment, the holding substrate 30 of the diaphragm element 18h is easily detachably attached to the attachment (diaphragm holding member, attaching body) 40. Moreover, a supporting unit 41 for supporting the attachment (attaching body) 40 is formed on a lower surface portion (wall portion of the vacuum chamber 4) 3a of the frame 3. The supporting unit 41 and the attachment 40 have cross-sectional shapes including concave and convex shapes that are associated with each other. Then, by allowing the attachment 40 to slide from the front side of the drawing toward the rear side of the drawing in FIG. 20, the attachment 40 can be easily attached to the supporting unit 41 without falling down. That is, by attaching the attachment 40 to which the holding substrate 30 is attached to the supporting unit 41 (lower surface portion 3a of the frame 3), the diaphragm element 18h can be attached to the lower surface portion 3a of the frame 3.

On the lower surface portion 3a of the frame 3, that is, on the rear side of the drawing of the supporting unit 41 in FIG. 20, a stopper (illustration thereof is omitted) for stopping the attachment 40 at a predetermined position is provided. The stopper (illustration thereof is omitted) is provided such that when the attachment 40 is stopped at the predetermined position, the opening portion 3b formed on the lower surface portion 3a of the frame 3 and the diaphragm (film portion) 19 of the diaphragm element 18h in which the holding substrate 30 is attached to the attachment 40 are overlapped with each other, when seen in a plan view.

The attachment (attaching body) 40 is desirably made of a material containing metal. By using the material containing metal as the material for the attachment 40, the attachment 40 and the frame 3 can be connected with each other electrically at low resistance, so that the electric potential of the attachment 40 and the electric potential of the frame 3 can be set to an equal electric potential. Moreover, when the frame 3 is grounded, with the electric potential of the frame 3 being 0 electric potential (earthed), the electric potential of the attachment 40 can be set to 0 electric potential (earthed).

Between the frame 3 and the attachment 40, a sealing member 42 is provided. The sealing member 42 air-tightly seals a portion between the frame 3 and the attachment 40. As the sealing member 42, for example, an O-ring may be used. Alternatively, in place of the installation of the sealing member 42, the frame 3 and the attachment 40 may be made in contact with each other in a state that a vacuum grease is applied between the frame 3 and the attachment 40, so that the portion between the frame 3 and the attachment 40 can be air-tightly sealed.

As shown in FIG. 21 and FIG. 22, the attachment (attaching body) 40 has a main surface 40a and a main surface 40b on the opposite side of the main surface 40a. On the main surface 40a side, a concave portion 43 is provided in the center of the attachment 40, and the holding substrate 30 of the diaphragm element (diaphragm member) 18h can be easily detachably attached to the concave portion 43. On the upper side and the left side of the concave portion 43 in FIG. 21, pressing jigs 44, 45, which are allowed to freely slide upward and downward, as well as rightward and leftward in FIG. 21, are provided, and on the pressing jigs 44 and 45, screws 46 and 47 for use in fixing the pressing jigs 44 and 45 are provided.

Moreover, between the bottom surface of the concave portion 43 and the holding substrate 30 attached to the concave portion 43, a sealing member 48 is provided. The sealing member 48 air-tightly seals a portion between the attachment 40 and the holding substrate 30. As the sealing member 48, a soft material is desirably used so as to air-tightly seal the portion between the attachment 40 and the holding substrate 30, without causing damages to the attachment 40 and the holding substrate 30, and, for example, an O-ring may be used. Alternatively, in place of the installation of the sealing member 48, the attachment 40 and the holding substrate 30 may be made in contact with each other in a state that a vacuum grease is applied between the attachment 40 and the holding substrate 30, so that the portion between the holding substrate 30 and the attachment 40 can be air-tightly sealed.

Upon attaching the holding substrate 30 of the diaphragm element 18h to the attachment 40, by attaching the holding substrate 30 to the concave portion 43, as well as by allowing the pressing jigs 44 and 45 to slide, the holding substrate 30 is pressed onto the lower side and the right side of the concave portion 43, as shown in FIG. 21. With the holding substrate 30 being pressed onto the concave portion 43, the holding substrate 30 is secured thereto by the screws 46 and 47. By using the attachment 40 with these pressing jigs 44 and 45 being provided therein, even in the case when the diaphragm elements 18h are exchanged, the position of the diaphragm 19 can be always adjusted to the center position of the attachment 40. For this reason, by using the attachment 40 and the supporting unit 41 in combination, the charged particle beam is always allowed to pass through the center of the diaphragm 19, so that it becomes possible to shorten the adjusting time before the observation of the sample 12.

In FIG. 21, guides 49 are formed on portions on the both left and right sides relative to the center of the attachment 40. The guides 49 are used for attaching the attachment 40 with the holding substrate 30 attached thereto to the supporting unit 41, while preventing the attachment 40 from falling down. As described earlier by reference to FIG. 20, the guide 49 is formed such that the supporting unit 41 and the attachment 40 are allowed to form cross-sectional shapes including concave and convex shapes associated with each other.

As shown in FIG. 22, in the case when the holding substrate (base substrate) 30 is attached to the concave portion 43, desirably, the main surface 30a of the holding substrate 30 is allowed to form the same surface as the main surface 40a of the attachment 40, or the main surface 30a thereof is allowed to protrude over the main surface 40a. Thus, it becomes possible to prevent the sample 12 held on the sample stage (holding unit) 22 from coming into contact with the main surface 40a of the attachment 40.

When the diaphragm element 18h shown in FIG. 18 or the diaphragm element 18g shown in FIG. 17 is used as the diaphragm element, the pressing jigs 44 and 45 are desirably made of a conductive material. By using the conductive material as the material for the pressing jigs 44 and 45, the sealing film (film portion) 35, the pressing jigs 44, 45 and the attachment 40 can be electrically connected to one another at low resistance. Thus, of secondary charged particles discharged from the sample 12, those particles that are not transmitted or not passed through the diaphragm 19 can be released outside the diaphragm element through the sealing film 35, the pressing jigs 44, 45 and the attachment 40. For this reason, it becomes possible to prevent the reduction in the sensitivity caused by the accumulation of the secondary charged particles on the buffer film 33 or the diaphragm 19.

Moreover, with respect to the diaphragm element 18h shown in FIG. 18 or the diaphragm element 18g shown in FIG. 17, in the case when the sealing film 35 is also formed on the side face 30f of the holding substrate (base substrate) 30, the sealing film 35 and the pressing jigs 44, 45 can be electrically connected to one another at further lower resistance. For this reason, it becomes possible to more effectively prevent the reduction in the sensitivity caused by the accumulation of secondary charged particles on the buffer film 33 or the diaphragm 19.

### Third Embodiment

Next, a charged particle beam device in accordance with a third embodiment of the present invention will be explained. The charged particle beam device of the present third embodiment has a configuration in which a supply unit that supplies a gas is added to the charged particle beam device of the first embodiment. Therefore, of the charged particle beam device of the third embodiment, those parts other than the supply unit are the same as those of the charged particle beam device of the first embodiment, and the description thereof will be omitted. Moreover, with respect to effects obtained by those parts other than the supply unit of the charged particle beam device of the third embodiment, the same effects as those by the charged particle beam device of the first embodiment are obtained, and the description thereof will be omitted.

FIG. 23 is an overall structural view of a charged particle beam device in accordance with the third embodiment.

As shown in FIG. 23, a charged particle beam device 1b of the third embodiment has a structure in which a supply unit 50 for supplying a gas between the diaphragm element (diaphragm member) 18a and the sample 12 is provided. The supply unit 50 includes a gas cylinder 51, a gas supply pipe 52 and a gas controlling valve 53. The gas cylinder 51 is provided outside the vacuum chamber 4. One end of the gas supply pipe 52 is connected to the gas cylinder 51, and the other end of the gas supply pipe 52 is opened in the vicinity of the diaphragm element 18a. In the middle portion of the gas supply pipe 52, the gas controlling valve 53 is provided, so that the opening/closing operation of the gas controlling valve 53 and the degree of opening thereof are controlled by the control unit 15.

By using this configuration, the opening/closing operation of the gas controlling valve 53 and the degree of opening thereof are controlled by the control unit 15, so that a gas can be supplied between the diaphragm element 18a and the sample 12 through the gas supply pipe 52.

Additionally, with respect to the gas cylinder 51, such a cylinder that is prepared as one portion of the charged particle beam device 1b may be used; however, such a cylinder that is prepared separately from the charged particle beam device 1b may be used.

In the case when there is air between the diaphragm element 18a and the sample 12, a primary charged particle beam that has transmitted or passed through the diaphragm element (film portion) 19 and secondary charged particles discharged from the sample 12 are scattered by gaseous molecules contained in the air. For this reason, the amount of the primary charged particle beam reaching the sample 12 is reduced, and the amount of the secondary charged particles reaching the detector 13 is consequently reduced. On the other hand, by supplying, for example, a gas composed of gaseous molecules having a molecular weight smaller than the average molecular weight of air, that is, a gas lighter than air, between the diaphragm (film portion) 19 and the sample 12, it becomes possible to allow the possibility of the primary charged particle beam and the secondary charged particles being scattered to be smaller. Thus, the amount of the primary charged particle beam reaching the sample 12 can be increased, so that the amount of the secondary charged particles reaching the detector 13 can be consequently increased.

Therefore, as the gas to be supplied by the supply unit 50, for example, a gas lighter than air, such as a nitrogen (N₂) gas or a steam gas, may be used; thus, it is possible to improve the S/N ratio of the image. Moreover, as the gas to be supplied by the supply unit 50, more desirably, a gas having a molecular weight smaller than the molecular weight of N₂ gas or steam gas, such as a helium (He) gas or a hydrogen (H₂) gas, may be used. By using such a gas, it becomes possible to further improve the S/N ratio of the image.

Additionally, the observing process by the use of the charged particle beam device 1b of the third embodiment can be executed in the same manner as in the observing process by the charged particle beam device 1 of the first embodiment, except that the processes of step S15 to step S18 of FIG. 19 are carried out, while supplying a gas between the diaphragm element 18a and the sample 12.

### Fourth Embodiment

Next, a charged particle beam device in accordance with a fourth embodiment of the present invention will be explained. The charged particle beam device of the first embodiment includes the charged particle optical lens barrel and the frame, and the vacuum chamber is partitioned by the charged particle optical lens barrel and the frame. In contrast, the charged particle beam device of the fourth embodiment includes a second frame in addition to the charged particle optical lens barrel and the first frame, and by attaching the second frame to the first frame, the vacuum chamber is partitioned by the charged particle optical lens barrel, the first frame and the second frame.

Additionally, in the following description, explanations will be given by exemplifying a configuration in which the charged particle beam device of the fourth embodiment is applied to a desktop-type scanning electron microscope. However, it is needless to say that the charged particle beam device of the fourth embodiment is also applicable to other various kinds of charged particle beam devices such an ion microscope.

### Configuration of Scanning Electron Microscope

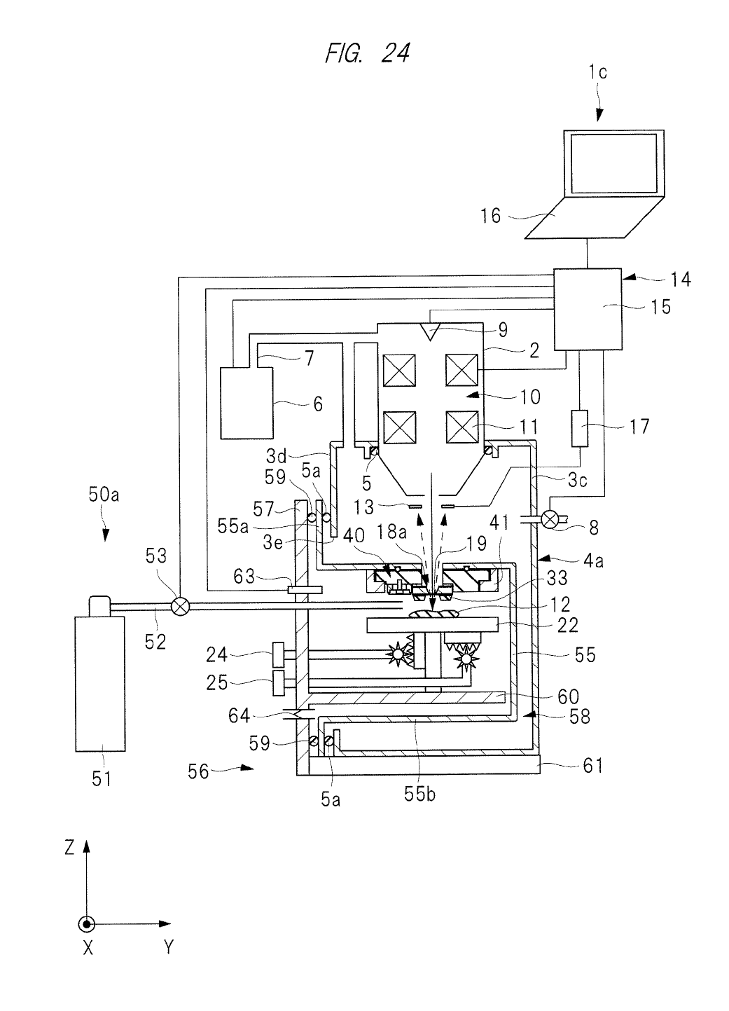

FIG. 24 is an overall structural view of a scanning electron microscope in accordance with a forth embodiment.

As shown in FIG. 24, a scanning electron microscope (charged particle beam device) 1c of the fourth embodiment includes the charged particle optical lens barrel 2, the frame 3c and a frame member (member for charged particle beam device) 56. The frame member 56 includes a frame 55, the diaphragm element (diaphragm member) 18a, the sample stage (holding unit) 22, the Z-axis driving unit 24 and a lid member 57. By attaching the frame 55 of the frame member 56 to the frame 3c, a vacuum chamber 4a is partitioned by the charged particle optical lens barrel 2, the frame 3c and the frame 55.

In the same manner as in the charged particle optical lens barrel 2 of the first embodiment, the charged particle optical lens barrel 2 in accordance with the fourth embodiment also has a structure in which, for example, on the upper side of the frame 3c, the lower portion of the charged particle optical lens barrel 2 is provided so as to protrude toward the inside of the frame 3c. The charged particle optical lens barrel 2 is attached to the frame 3c through a sealing member (O-ring) 5, and the frame 55 is attached to the frame 3c through the sealing member (O-ring) 5a. Therefore, the vacuum chamber 4a partitioned by the charged particle optical lens barrel 2, the frame 3c and the frame 55 is air-tightly provided.

In the example shown in FIG. 24, an opening portion 3e is provided, for example, on a side face portion 3d of the frame 3c. The frame 55 includes a side face portion 55a that is provided, for example, in a manner so as to seal the opening portion 3e, and a concave portion 55b that is integrally provided together with the side face portion 55a so as to retreat from the opening portion 3e of the frame 3c toward the center of the frame 3c. The concave portion 55b is provided such that when the frame 55 is attached to the frame 3c, the sample chamber 58 partitioned by the concave portion 55b is positioned below the charged particle optical lens barrel 2.

The lid member 57 is provided in the frame 55. The lid member 57 is detachably attached to the frame 55, and by attaching the lid member 57 to the frame 55, the sample chamber 58 is partitioned by the frame 55 and the lid member 57. Moreover, the space inside the sample chamber 58 corresponds to the outside space of the vacuum chamber 4a. The lid member 57 is attached to the frame 55 through a sealing member (O-ring) 59. Therefore, the sample chamber 58 partitioned by the frame 55 and the lid member 57 is air-tightly provided.

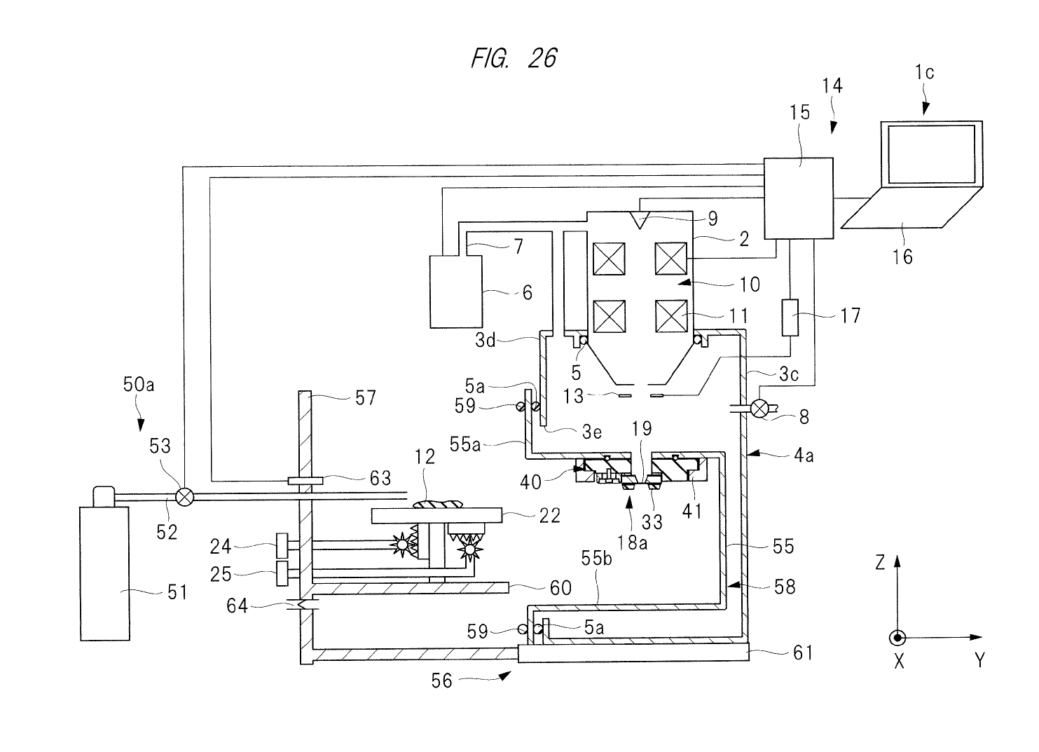

In the example shown in FIG. 24, the lid member 57 is attached to the side face portion 55a of the frame 55 through the sealing member 59, so that the sample chamber 58 is partitioned by the lid member 57 and the concave portion 55b. Moreover, the lid member 57 is brought into a detached state from the frame 55, by sliding (moving) leftward from the position shown in FIG. 24, as explained by using FIG. 26 to be described later.

Outside the vacuum chamber 4a partitioned by the charged particle optical lens barrel 2, the frame 3c and the frame 55, the vacuum pump 6 (exhaust unit) 6 is formed. The vacuum pump 6 is connected to the charged particle optical lens barrel 2 and the frame 3c by a vacuum pipe 7. That is, the vacuum pump 6 is connected to the vacuum chamber 4a.

At the time of use of the scanning electron microscope (charged particle beam device) 1c, the vacuum chamber 4a is exhausted by the vacuum pump 6, so that the pressure inside the vacuum chamber 4a is reduced to vacuum. In other words, the vacuum chamber 4a is exhausted by the vacuum pump 6, and the pressure inside the vacuum chamber 4a is maintained in a reduced-pressure state more than the pressure outside the vacuum chamber 4a.

Additionally, also in the fourth embodiment, only one vacuum pump 6 is illustrated in the same manner as in the first embodiment; however, two or more vacuum pumps 6 may be used.

In the fourth embodiment, the leak valve 8 is attached to the frame 3c in the same manner as in the first embodiment. The leak valve 8 is used for releasing the vacuum chamber 4a partitioned by the charged particle optical lens barrel 2, the frame 3c and the frame 55 to the atmosphere.

The configurations of the charged particle optical lens barrel 2 and the control system 14 can be respectively designed in the same manner as in the charged particle optical lens barrel 2 and the control system 14 in the charged particle beam device 1 of the first embodiment. Moreover, in the same manner as in the first embodiment, the detector 13 is attached to the portion of the charged particle optical lens barrel 2 protruding toward the inside of the frame 3c.

### Inside of Sample Chamber

On a portion that partitions the vacuum chamber 4a and the sample chamber 58, corresponding to the frame 55, a diaphragm element (diaphragm member) 18a is provided in the same manner as in the first embodiment. In the example shown in FIG. 24, on a portion which is positioned below the charged particle optical lens barrel 2, corresponding to the concave portion (wall portion of the vacuum chamber 4a) 55b of the frame 55, the diaphragm element 18a is provided. The diaphragm element 18a includes the diaphragm 19 that allows a primary charged particle beam to transmit or pass therethrough, and air-tightly separates the inside of the vacuum chamber 4a and the inside of the sample chamber 58 from each other.

In the fourth embodiment, explanations will be given by exemplifying a configuration using the diaphragm element 18a as the diaphragm element in the same manner as in the first embodiment, as a typical example. However, in place of the diaphragm element 18a, the respective diaphragm elements 18b to 18h explained in the first modification example to seventh modification example of the first embodiment may be used as the diaphragm element.

In the example shown in FIG. 24, in the same manner as in the second embodiment, the holding substrate of the diaphragm element 18a can be easily detachably attached to the attachment (diaphragm holding member, attaching body) 40. Moreover, a supporting unit 41 for supporting the attachment 40 is formed in the concave portion 55b of the frame 55, in the same manner as in the second embodiment.

Additionally, the method for attaching the diaphragm element 18a to the frame 55 is not limited by the method using the attachment 40. For example, as explained in the first embodiment, the diaphragm element 18a may be attached to the frame 55 by bonding a portion on the periphery of the diaphragm 19 to a portion on the periphery of the opening formed on the concave portion 55b of the frame 55 by using the bonding member 21 (see FIG. 2).

The sample stage (holding unit) 22 is provided on the inside of the sample chamber 58 corresponding to the outside of the vacuum chamber 4a. In the same manner as in the first embodiment, the sample stage 22 is used for holding the sample 12. In the fourth embodiment, the sample stage 22 is assembled on a support member 60, and the support member 60 is attached to the lid member 57. Therefore, the sample stage 22 is attached to the lid member 57.

Moreover, inside the sample chamber 58, the Z-axis driving unit 24 and X, Y-axes driving unit 25 are provided. In the same manner as in the first embodiment, the Z-axis driving unit 24 drives the sample stage 22 to move, for example, in the Z-axis direction, that is, in the vertical direction, and by changing the height position of the sample stage 22, the distance between the sample 12 held on the sample stage 22 and the diaphragm element 18a along the Z-axis direction is adjusted. In the same manner as in the first embodiment, by driving the sample stage 22 to move, for example, in the X-axis direction and Y-axis direction that are two directions intersecting with each other on a horizontal plane, the X, Y-axes driving unit 25 moves the sample 12 held on the sample stage 22 in the X-axis direction as well as in the Y-axis direction.

As described earlier, the lid member 57 is designed to be detachably attached to the frame 55. More specifically, the lid member 57 is provided so as to be slidable (drawable) relative to, for example, a bottom plate 61 and the frame 55 secured and supported onto the bottom plate 61. With this structure, as explained by using FIG. 26 to be described later, by allowing the lid member 57 to slide leftward in FIG. 24, the sample stage 22 can be drawn outside the sample chamber 58, so that the samples 12 held on the sample stage 22 can be exchanged.

Moreover, as described earlier, since the lid member 57 is secured to the frame 55 by attaching thereto, through the frame 55 and the sealing member (O-ring) 59, it is designed so that the support plate 60 is not moved, while observing the sample 12.

As shown in FIG. 24, in the scanning electron microscope (charged particle beam device) 1c of the fourth embodiment, a supply unit 50a for supplying a gas between the diaphragm element (diaphragm member) 18a and the sample 12 is provided. The supply unit 50a includes the gas cylinder 51, the gas supply pipe 52, the gas controlling valve 53, a pressure gauge 63 and a pressure adjusting valve 64. The gas cylinder 51 is provided outside the vacuum chamber 4a. One end of the gas supply pipe 52 is connected to the gas cylinder 51, and the other end of the gas supply pipe 52 is opened inside the sample chamber 58, that is, in the vicinity of the diaphragm element 18a. In the middle portion of the gas supply pipe 52, the gas controlling valve 53 is provided. The opening/closing operation of the gas controlling valve 53 and the pressure adjusting valve 64 and the degree of opening thereof are controlled by the control unit 15 based upon measured values of the pressure gauge 63.

By using this configuration, the opening/closing operation and of the gas controlling valve 53 the degree of opening thereof are controlled by the control unit 15, so that a gas can be supplied between the diaphragm element 18a and the sample 12 through the gas supply pipe 52. Moreover, by controlling the opening/closing operation of the pressure adjusting valve 64 and the degree of opening thereof by using the control unit 15, the inside of the sample chamber 58 can be easily replaced by the gas supplied through the gas supply pipe 52.

Additionally, with respect to the gas cylinder 51, such a cylinder that is prepared as one portion of the scanning electron microscope 1c may be used; however, such a cylinder that is prepared separately from the scanning electron microscope 1c may also be used.

As described in the third embodiment, by supplying a gas lighter than air between the diaphragm (film portion) 19 and the sample 12, it is possible to reduce the possibility of scattering of a primary charged particle beam that has transmitted or passed through the diaphragm 19 and secondary charged particles discharged from the sample 12. Thus, it is possible to increase the amount of the primary charged particle beam reaching the sample 12, and also to increase the amount of the secondary charged particles reaching the detector 13.

Therefore, as the gas to be supplied by the supply unit 50a, a gas lighter than air, such as a nitrogen (N₂) gas or a steam gas, may be used; thus, it is possible to improve the S/N ratio of the image. Moreover, as the gas to be supplied by the supply unit 50a, desirably, a gas having a molecular weight smaller than the molecular weight of N₂ gas or steam gas, such as a He gas or a H₂ gas, may be used. By using such a gas, it becomes possible to further improve the S/N ratio of the image.

In the case when a gas lighter than air is used as the gas supplied by the supply unit 50a, the supplied gas tends to remain in the upper portion inside the sample chamber 58. Therefore, desirably, the pressure adjusting valve 64 is provided on the lower portion of the lid member 57. Moreover, upon starting the supply of the gas by the supply unit 50a, while the gas is supplied from the gas supply pipe 52, the pressure adjusting valve 64 is opened so as to discharge air from the inside of the sample chamber 58. Thus, the inside of the sample chamber 58 can be easily replaced by the gas supplied by the supply unit 50a.

Alternatively, in place of the pressure adjusting valve 64, a three-way valve may be provided, and one end of the three-way valve may be connected to the vacuum pump (exhaust unit) 6. At this time, the vacuum pump 6 is connected to the sample chamber 58 through the three-way valve. Moreover, before starting the gas supply by the supply unit 50a, the three-way valve is switched, with the gas controlling valve 53 being closed, so that the sample chamber 58 is exhausted by the vacuum pump 6, and thereafter, the gas controlling valve 53 is opened. Thus, the inside of the sample chamber 58 can be more easily replaced with the gas supplied by the supply unit 50a.

Additionally, in the case when the vacuum pump 6 is connected to the sample chamber 58, the sample 12 can be observed in a state where although the pressure inside the sample chamber 58 is higher than the pressure inside the vacuum chamber 4a, it is reduced more than the atmospheric pressure. That is, although there is a pressure difference between the pressure inside the sample chamber 58 and the pressure inside the vacuum chamber 4a, the sample 12 can be observed in a state where the pressure inside the sample chamber 58 is reduced more than the atmospheric pressure.

In the fourth embodiment, the entire frame member 56 is provided in a manner so as to be attachable to the scanning electron microscope (charged particle beam device) 1c, with the frame 55 being provided so as to be attachable to the frame 3c. Moreover, by attaching the frame 55 to the frame 3c, the vacuum chamber 4a, which is partitioned by the charged particle optical lens barrel 2, the frame 3c and the frame 55, is air-tightly provided. In a state where the pressure inside the vacuum chamber 4a is reduced more than the pressure inside the sample chamber 58 by the vacuum pump 6, the primary charged particle beam passing through the inside of the vacuum chamber 4a and transmitted through the diaphragm element 18a provided in the frame 55 is radiated to the sample 12 held inside the sample chamber 58 so as to scan the sample 12.

Moreover, in the fourth embodiment, by optionally attaching the frame member 56 to a vacuum SEM for use in observing the sample in a vacuum state, an existing vacuum SEM can be easily modified into a non-vacuum SEM capable of observing a sample in a non-vacuum state such as under the atmospheric pressure. Therefore, it is possible to reduce costs required for introducing the non-vacuum SEM.

### Observing Process by Scanning Electron Microscope

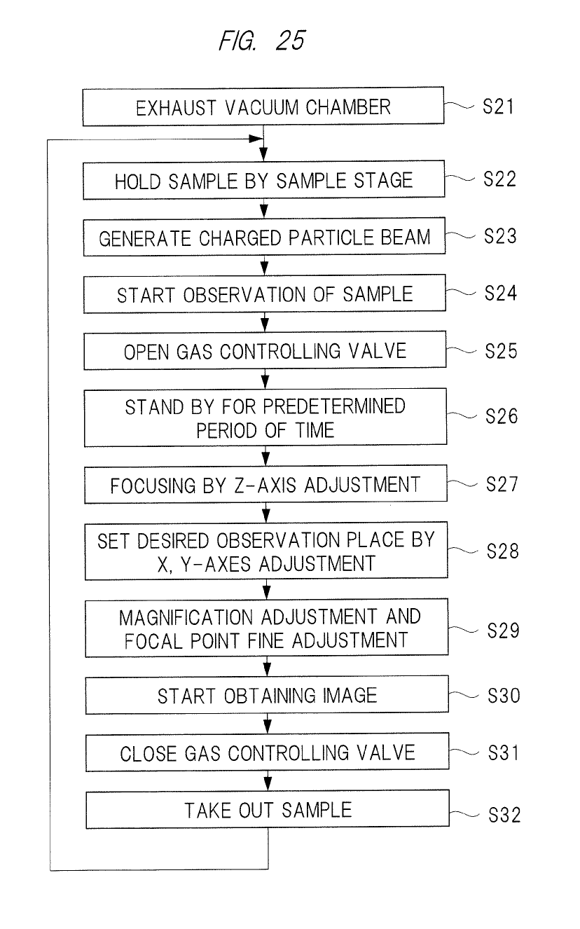

Next, observing processes by the scanning electron microscope 1c of the fourth embodiment will be explained. FIG. 25 is a flowchart showing parts of an observing process by the scanning electron microscope in accordance with the fourth embodiment. FIG. 26 is an overall structural view of the scanning electron microscope in the observing process in accordance with the fourth embodiment.

First, the vacuum chamber 4a is exhausted (Step S21). In this step S21, for example, by the vacuum pump (exhaust unit) 6 controlled by the control unit 15, the vacuum chamber 4a, partitioned by the charged particle optical lens barrel 2, the frame 3c and the frame 55, is exhausted through the vacuum pipe 7, so that the pressure inside the vacuum chamber 4a is reduced to vacuum. Therefore, the vacuum chamber 4a is maintained in a state where the pressure inside the vacuum chamber 4a is reduced more than the pressure inside the sample chamber 58, which corresponds to the outside of the vacuum chamber 4a, that is, in a state where there is a pressure difference between the inside of the vacuum chamber 4a and the outside (inside the sample chamber 58) of the vacuum chamber 4a.

Next, the sample 12 is held by the sample stage (holding unit) 22 (step S22). In this step S22, the sample 12 is mounted on the sample stage 22 to be held thereon. As shown in FIG. 26, by allowing the lid member 57 to slide, the sample 12 is mounted on the sample stage 22 to be held thereon in a state where the sample stage 22 on the support plate 60 is brought to a state drawn from the sample chamber 58. Moreover, in the same manner as in the process of step S12 in the first embodiment, the height position in the Z-axis direction of the sample stage 22 is preliminarily lowered sufficiently so as to prevent the sample 12 held on the sample stage 22 from coming into contact with the diaphragm element (diaphragm member) 18a.

Additionally, in the case when there is a pressure difference between the pressure inside the sample chamber 58 and the atmospheric pressure, upon allowing the lid member 57 to slide (to be drawn), the pressure inside the sample chamber 58 can be made equal to the atmospheric pressure by opening the pressure adjusting valve 64.

Next, a charged particle beam is generated (step S23). In this step S23, for example, the charged particle beam is generated by using, for example, the charged particle source 9 composed of an electron gun including filaments.

Next, an observation of the sample 12 is started (step S24). In this step S24, by adjusting conditions or the like of the optical lens 11 of the charged particle optical system 10 and displaying an image of the sample 12 on the personal computer 16, the observation is started. Additionally, at first, the magnification is set to a low level so as to smoothly carry out the next focusing process.

Next, the gas controlling valve 53 is opened (step S25). In this step S25, a gas cylinder filled with, for example, a He gas, is prepared as the gas cylinder 51, and by opening the gas controlling valve 53, for example, a He gas is introduced to a space inside the sample chamber 58 corresponding to a portion between the sample 12 and the diaphragm element 18a through the gas supply pipe 52.

In the case when the diaphragm element 18a shown in FIG. 4 or the diaphragm element 18d shown in FIG. 7 is used, a flow path FP corresponding to a region from which the buffer film 33 is removed is formed so as to pass through the center of the diaphragm element 18a or 18d, when seen in a plan view. With this structure, in the case when a gas lighter than air is supplied between the diaphragm element 18a or 18d and the sample 12, the supplied gas is positively allowed to flow between the diaphragm 19 and the sample 12, thereby making it possible to improve the S/N ratio of the image obtained by the scanning electron microscope. Moreover, since the supplied gas is positively allowed to flow between the diaphragm 19 and the sample 12, it is possible to reduce the gas supply amount, and also to carry out an observing process with high efficiency.

Moreover, even in the case when the diaphragm element 18b shown in FIG. 5 or the diaphragm element 18c shown in FIG. 6 is used, by devising the shape of the opening end on the sample 12 side of the gas supply pipe 52, the supplied gas is easily allowed to remain at a region surrounded by the pattern 33b or 33c made of the buffer film 33. With this configuration, it is possible to improve the S/N ratio of the image obtained by the scanning electron microscope. Furthermore, since the gas supply amount is reduced, the observing process can be efficiently carried out.

In the case when no buffer film 33 is formed on the diaphragm element at all, the supplied gas is diffused on the periphery of the diaphragm element. For this reason, in order to allow the supplied gas to stay between the diaphragm (film portion) 19 and the sample 12 at a high concentration, the gas needs to be continuously allowed to flow or the inside of the sample chamber 58 needs to be entirely replaced by a gas each time the samples 12 are exchanged, with the result that the gas supply amount might increase. Therefore, upon supplying a gas between the diaphragm element 18a and the sample 12, the buffer film 33 has a function for preventing the diaphragm 19 and the sample 12 from coming into contact with each other, and also has a function for reducing the amount of the gas supplied between the diaphragm element 18a and the sample 12.

Next, the process goes to a stand-by state for a predetermined period of time (step S26). In the case when the inside of the sample chamber 58 is replaced by a gas, for example, after carrying out the stand-by process for a predetermined period of time, with the pressure adjusting valve 64 being opened, the valve is closed, so that the inside of the sample chamber 58 is replaced by the gas supplied from the gas supply pipe 52, and the pressure inside the sample chamber 58 is consequently kept at a state (positive pressure state) slightly higher than the atmospheric pressure. Thus, since it becomes possible to more positively prevent or suppress the primary charged particle beam and the secondary charged particles that have transmitted or passed through the diaphragm element 18a from being scattered or attenuated, the S/N ratio of the image can be improved.

Additionally, in the case when, because of shapes or the like of the various patterns 33a to 33d made of the buffer film 33 shown in FIG. 4 to FIG. 7, the same effect as that in the case when the gas exchange is carried out is obtained even in the case when no gas exchange is carried out inside the sample chamber 58, the step of S26 can be omitted.

Next, a focusing process is carried out by the Z-axis adjustment (step S27). In this step S27, the height position of the sample 12 is gradually raised by using the Z-axis driving unit 24, while observing the image of the sample 12, and the focal point is adjusted so as to observe the sample 12 clearly.

Next, a desired observation place is set by the X, Y-axes adjustment (step S28). In this step S28, the sample 12 is moved to the desired observation place by using the X, Y-axes driving unit 25, while observing the image of the sample 12.

Next, magnification adjustment and focal point fine adjustment are carried out (step S29). In this step S29, the adjustment of the magnification and fine adjustments of the Z-axis driving unit 24 are carried out.

Next, an image obtaining process is started (step S30). In this step S30, a switch for obtaining the image is pressed, so that the image is obtained by the personal computer 16, and the obtained image is stored. Then, by repeating these operations a plurality of times, desired sample observing processes are carried out on the sample 12, so that the resulting images are obtained.

After completion of the observation, the gas controlling valve 53 is closed (step S31). In this step S31, the gas controlling valve 53 is closed, and the pressure adjusting valve 64 is opened, so that the gas filled inside the sample chamber 58 is discharged.

Additionally, the amount of the gas filled inside the sample chamber 58 is small, and since the pressure inside the sample chamber 58 becomes equal to the atmospheric pressure immediately soon after opening the pressure adjusting value 64, it is not necessary to carry out the stand-by process for a predetermined period of time in this step S31.

Next, the sample 12 is taken out (step S32). In this step S32, after completion of the observation, the height position of the sample 12 is lowered by using the Z-axis driving unit 24, so that the sample 12 is kept away from the diaphragm element (diaphragm member) 18a. Next, as explained by referring to FIG. 26, the lid member 57 is allowed to slide, and after the sample stage (holding unit) 22 positioned on the support plate 60 is drawn from the sample chamber 58, the sample 12 is taken out from the sample stage 22. Moreover, in the case when the next sample is observed, the operations from step S22 to step S32 are repeatedly carried out on the next sample.

Additionally, the flowchart of the observing process shown in FIG. 25 shows one example of operations of the scanning electron microscope, and the order of the respective processes is not limited by the order shown in FIG. 25. Therefore, the order of the respective processes of step S21 to step S32 can be altered appropriately.

### Main Characteristics and Effects of Present Embodiments

In the same manner as in the charged particle beam device 1 of the first embodiment, the diaphragm element (diaphragm member) 18a is also provided in the scanning electron microscope (charged particle beam device) 1c of the fourth embodiment. Moreover, in the diaphragm element 18a, the buffer film (film portion) 33 for preventing the diaphragm (film portion) 19 and the sample 12 from coming into contact with each other is formed along the Z-axis direction so as to be positioned on the sample 12 side (on the sample stage 22 side) rather than on the diaphragm 19.

With this configuration, in the same manner as in the charged particle beam device 1 of the first embodiment, it is possible to prevent the diaphragm 19 and the sample 12 from coming into contact with each other, and consequently to prevent the diaphragm 19 from being damaged. Therefore, since the observed image can be captured stably with a high resolution, the performance of the scanning electron microscope can be improved.

Moreover, in the same manner as in the charged particle beam device 1 of the first embodiment, it is possible to prevent the diaphragm 19 and another member from coming into contact with each other and consequently to prevent the diaphragm 19 from being damaged.

In particular, in the case when there is a pressure difference between the inside of the vacuum chamber 4a and the outside of (inside the sample chamber 58) the vacuum chamber 4a, in the same manner as in the charged particle beam device 1 of the first embodiment, the effect for preventing the diaphragm 19 and the sample 12 from coming into contact with each other can be improved.

Moreover, in the fourth embodiment, the frame member 56, which is composed of the frame 55, the diaphragm element 18a, the sample stage 22, the Z-axis driving unit 24 and the lid member 57, is used. Furthermore, by attaching the frame 55 of the frame member 56 to the frame 3c of a generally-used SEM, the SEM having a pressure difference between the inside of the vacuum chamber 4a and the inside of the sample chamber 58 is constructed. Therefore, by optionally attaching the frame member 56 to a vacuum SEM for use in observing a sample in a vacuum state, an existing vacuum SEM can be easily modified into a non-vacuum SEM capable of observing the sample in a non-vacuum state such as under the atmospheric pressure. Moreover, upon introducing the non-vacuum SEM, it is possible to reduce costs required introducing the non-vacuum SEM.

### Fifth Embodiment

Next, a charged particle beam device in accordance with a fifth embodiment of the present invention will be explained. In the charged particle beam device of the fourth embodiment, the lid member is provided. In contrast, in the charged particle beam device in accordance with the fifth embodiment, no lid member is provided, and the sample chamber is not air-tightly provided.

Additionally, in the following description, explanations will be given by exemplifying a configuration in which the charged particle beam device of the fifth embodiment is applied to a desktop-type scanning electron microscope. However, it is needless to say that the charged particle beam device of the fifth embodiment is also applicable to other various kinds of charged particle beam devices such as an ion microscope.

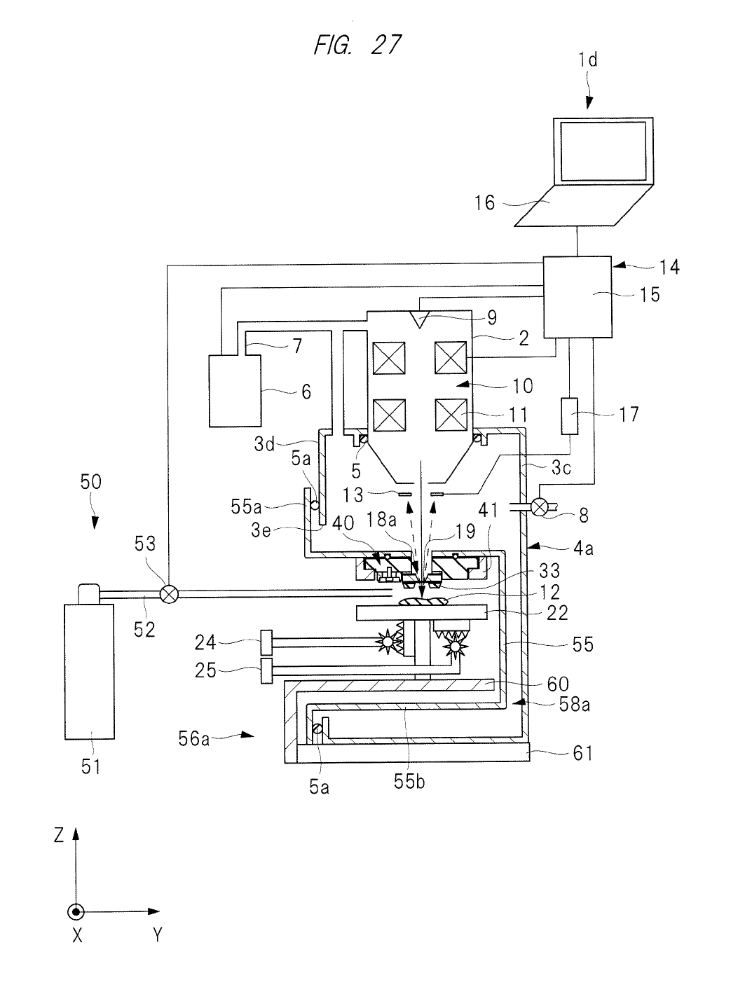

FIG. 27 is an overall structural view of a scanning electron microscope in accordance with the fifth embodiment.

Of the scanning electron microscope (charged particle beam device) 1d of the fifth embodiment, parts other than a frame member 56a and the supply unit 50 are the same as those parts other than the frame member 56 and the supply unit 50a of the scanning electron microscope 1c of the fourth embodiment; therefore, the description thereof will be omitted.

As shown in FIG. 27, in the scanning electron microscope 1d of the fifth embodiment as well, the charged particle optical lens barrel 2, the frame 3c and the frame member 56a are provided. The frame member 56a includes the frame 55, the diaphragm element (diaphragm member) 18a, the sample stage (holding unit) 22 and the Z-axis driving unit 24. By attaching the frame 55 of the frame member 56a to the frame 3c, the vacuum chamber 4a is partitioned by the charged particle optical lens barrel 2, the frame 3c and the frame 55.

Also, in the fifth embodiment, the opening portion 3e is provided, for example, on the side face portion 3d of the frame 3c. The frame 55 includes the side face portion 55a that is provided, for example, in a manner so as to seal the opening portion 3e, and the concave portion 55b that is integrally provided together with the side face portion 55a so as to retreat from the opening portion 3e of the frame 3c toward the center of the frame 3c. The concave portion 55b is provided such that when the frame 55 is attached to the frame 3c, the sample chamber 58a surrounded by the concave portion 55b is positioned below the charged particle optical lens barrel 2.

On the other hand, in the fifth embodiment, no lid member 57 (see FIG. 24) is provided on the frame 55. That is, in the fifth embodiment, the sample chamber 58a is not air-tightly provided.

The sample stage (holding unit) 22 is assembled on the support member 60, and the support member 60 is provided so as to be slidable (drawable) relative to, for example, the bottom plate 61 and the frame 55 secured and supported onto the bottom plate 61. With this configuration, by sliding the support member 60 leftward in FIG. 27, the sample stage 22 can be drawn outside the sample chamber 58a, so that the samples 12 to be held by the sample stage 22 can be exchanged.

As shown in FIG. 27, in the same manner as in the charged particle beam device 1b of the third embodiment, in the scanning electron microscope (charged particle beam device) 1d of the fifth embodiment, the supply unit 50 for supplying a gas between the diaphragm element (diaphragm member) 18a and the sample 12 is provided. The supply unit 50 includes the gas cylinder 51, the gas supply pipe 52 and the gas controlling valve 53. Moreover, since the sample chamber 58a is not air-tightly provided, the pressure gauge 63 (see FIG. 24) and the pressure adjusting valve 64 (see FIG. 24) are not provided therein, which is different from the scanning electron microscope 1c of the fourth embodiment.

Also, in the fifth embodiment, a gas lighter than air can be used as the gas to be supplied between the diaphragm element 18a and the sample 12, in the same manner as in the fourth embodiment, and with this configuration, the S/N ratio of the image can be improved.

The observing process by the scanning electron microscope 1d of the fifth embodiment can be carried out in the same manner as in the observing process by the scanning electron microscope 1c of the fourth embodiment, except that the process of step S26 is not carried out because the pressure gauge 63 and the pressure adjusting valve 64 (see FIG. 24) are not provided therein.

In the same manner as in the scanning electron microscope 1 of the first embodiment, the diaphragm element (diaphragm member) 18a is also provided in the scanning electron microscope 1d of the fifth embodiment. Moreover, in the diaphragm element 18a, the buffer film (film portion) 33, which prevents the diaphragm (film portion) 19 and the sample 12 from coming into in contact with each other, is provided along the Z-axis direction so as to be positioned on the sample 12 side (the sample stage 22 side) rather than on the diaphragm 19.

By using this configuration, it becomes possible to prevent the diaphragm 19 and the sample 12 from coming into contact with each other, and consequently to prevent the diaphragm 19 from being damaged, in the same manner as in the charged particle beam device 1 of the first embodiment. Therefore, since the observed image can be captured stably with a high resolution, the performance of the scanning electron microscope can be improved.

Moreover, in the same manner as in the charged particle beam device 1 of the first embodiment, it is possible to prevent the diaphragm 19 from coming into contact with another member, and consequently to prevent the diaphragm 19 from being damaged.

In particular, in the case when there is a pressure difference between the inside of the vacuum chamber 4a and the outside of the vacuum chamber 4a, the effect for preventing the diaphragm 19 and the sample 12 from coming into contact with each other is improved in the same manner as in the charged particle beam device 1 of the first embodiment.

Additionally, in place of the diaphragm element 18a, the diaphragm elements 18b to 18h explained in the first to seventh modification examples of the first embodiment may be used as the diaphragm element.

Moreover, in the fifth embodiment, the frame member 56a may be optionally attached to the vacuum SEM for use in observing the sample in a vacuum state, in the same manner as in the fourth embodiment. Thus, an existing vacuum SEM can be easily modified into a non-vacuum SEM capable of observing a sample in a non-vacuum state such as under the atmospheric pressure. Therefore, it is possible to reduce costs required for introducing the non-vacuum SEM.

Additionally, the same members as those provided in the vacuum SEM may be used as the sample stage (holding unit) 22 and the Z-axis driving unit 24. In this case, the corresponding structure including only the frame 55 and the diaphragm element (diaphragm member) 18a may be used as the frame member.

In the foregoing, the invention made by the inventors of the present invention has been concretely described based on the embodiments. However, it is needless to say that the present invention is not limited to the foregoing embodiments and various modifications and alterations can be made within the scope of the present invention.

### INDUSTRIAL APPLICABILITY

The present invention can be effectively applied to a charged particle beam device.

### EXPLANATIONS OF REFERENCE NUMERALS

1, 1a, 1b Charged particle beam device
1c, 1d Scanning electron microscope (charged particle beam device)
2 Charged particle optical lens barrel
3, 3c Frame
3a Lower surface portion (wall portion)
3b Opening portion
3d Side face portion
3e Opening portion
4, 4a Vacuum chamber
5, 5a Sealing member (O-ring)
6 Vacuum pump (exhaust unit)
7 Vacuum pipe
8 Leak valve
9 Charged particle source
10 Charged particle optical system
11 Optical lens
12 Sample
13 Detector
14 Control system
15 Control unit
16 Personal computer
17 Amplifier
18a to 18h Diaphragm element (diaphragm member)
19 Diaphragm (membrane, film portion)
21 Bonding member
22 Sample stage (holding unit)
23 Mount portion
24 Z-axis driving unit
25 X, Y-axes driving unit
30 Holding substrate (base substrate)
30a, 30b Main surface
30c to 30e Region
30f Side face
31 Thin film
31a Opening portion
32 Through-hole
32a Opening
33 Buffer film (film portion)
33a to 33d Pattern
34 Insulating film
34a, 34b Pattern
35 Sealing film (film portion)
40 Attachment (diaphragm holding member, attaching body)
40a, 40b Main surface
41 Supporting unit
42 Sealing member
43 Concave portion
44, 45 Pressing jig
46, 47 Screw
48 Sealing member
49 Guide
50, 50a Supply unit
51 Gas cylinder
52 Gas supply pipe
53 Gas controlling valve
55 Frame
55a Side face portion
55b Concave portion
56, 56a Frame member (member for charged particle beam device)
57 Lid member
58, 58a Sample chamber
59 Sealing member (O-ring)
60 Support plate
61 Bottom plate
63 Pressure gauge
64 Pressure adjusting valve
d1 to d5 Width dimension
FP Flow path

1. A member for a charged particle beam device, which is used for the charged particle beam device in which a charged particle beam passing through an inside of a first chamber that is partitioned by a first frame and a second frame and air-tightly provided, is radiated to a sample held on an outside of the first chamber so as to scan the sample, the member comprising:
the second frame attached to the first frame;
a diaphragm member that is provided in the second frame, and includes a first film portion that air-tightly separates the inside of the first chamber and the outside of the first chamber from each other, when the second frame is attached to the first frame, in a state where a pressure inside the first chamber is reduced more than a pressure outside the first chamber by an exhaust unit that exhausts the first chamber, and allows the charged particle beam passing through the inside of the first chamber to be transmitted therethrough;
a holding unit that holds the sample outside the first chamber, when the second frame is attached to the first frame; and
a driving unit that adjusts a distance between the sample held on the holding unit and the diaphragm member by driving the diaphragm member or the holding unit,
wherein the diaphragm member includes a second film portion that is formed so as to be positioned on the holding unit side rather than on the first film portion when the second frame is attached to the first frame, and
the second film portion prevents the sample held on the holding unit and the first film portion from coming into contact with each other.

2. A charged particle beam device comprising:
a first chamber that is air-tightly provided;
an exhaust unit that exhausts the first chamber;
a holding unit that holds a sample outside the first chamber;
a diaphragm member that is provided in a wall portion of the first chamber, and includes a first film portion that air-tightly separates an inside of the first chamber and an outside of the first chamber from each other, in a state where a pressure inside the first chamber is reduced more than a pressure outside the first chamber by the exhaust unit, and allows a charged particle beam passing through the inside of the first chamber to be transmitted therethrough;
a charged particle optical system that radiates the charged particle beam transmitted through the first film portion to the sample held on the holding unit so as to scan the sample; and
a driving unit that changes a distance between the sample held on the holding unit and the diaphragm member by driving the holding unit or the diaphragm member,
wherein the diaphragm member includes a second film portion that is formed so as to be positioned on the holding unit side rather than on the first film portion, and
the second film portion prevents the sample held on the holding unit and the first film portion from coming into contact with each other.

3. The charged particle beam device according to claim 2,
wherein the diaphragm member includes a substrate having a first main surface that faces the outside of the first chamber and a second main surface that is positioned on an opposite side of the first main surface,
the substrate has a through-hole that reaches from the first main surface to the second main surface formed therein,
the first film portion is formed on the first main surface so as to cover an opening of the through-hole, and
the second film portion is formed on the first main surface.

4. The charged particle beam device according to claim 3,
wherein the second film portion is formed on two regions that sandwich a region in which the first film portion is formed, of the first main surface, when seen in a plan view.

5. The charged particle beam device according to claim 3,
wherein the first film portion is formed in a center of the first main surface when seen in a plan view, and
the second film portion is formed in a region separated toward a peripheral edge side from a region in which the first film portion is formed and also separated toward the center side from a peripheral edge of the substrate, of the first main surface, when seen in a plan view.

6. The charged particle beam device according to claim 2,
wherein the first film portion is made of silicon nitride, aluminum nitride or polyimide.

7. The charged particle beam device according to claim 3,
wherein the diaphragm member includes an attaching body to which the substrate is attached, and by attaching the attaching body having the substrate attached thereto to the wall portion, the diaphragm member is provided on the wall portion.

8. The charged particle beam device according to claim 7,
wherein the diaphragm member includes a sealing member that air-tightly seals a portion between the substrate and the attaching body,
the attaching body includes a third main surface that faces the outside of the first chamber when the attaching body is attached to the wall portion, and a fourth main surface that is positioned on an opposite side of the third main surface,
the substrate is attached to the third main surface side of the attaching body, and
when the substrate is attached to the attaching body, the first main surface forms a same surface as the third main surface or the first main surface protrudes over the third main surface.

9. The charged particle beam device according to claim 3,
wherein the diaphragm member includes a third film portion formed on a surface of the second film portion, and
the third film portion is made of a conductive film.

10. The charged particle beam device according to claim 9,
wherein the third film portion is formed on a surface of the second film portion and a side face of the substrate.

11. The charged particle beam device according to claim 2, comprising:
a first frame and a second frame,
wherein the first chamber is partitioned by the first frame and the second frame, and
the diaphragm member is provided in the second frame serving as the wall portion of the first chamber.

12. The charged particle beam device according to claim 11, comprising:
a lid member; and
a second chamber partitioned at the outside of the first chamber by the second frame and the lid member,
wherein the holding unit holds the sample inside the second chamber, and
the second film portion air-tightly separates the inside of the first chamber and the inside of the second chamber from each other in a state where a pressure inside the first chamber is reduced more than a pressure inside the second chamber by the exhaust unit, and allows the charged particle beam to be transmitted therethrough.

13. The charged particle beam device according to claim 2, comprising:
a supply unit that supplies a gas lighter than air between the sample held on the holding unit and the diaphragm member.

14. A diaphragm member which is attached to a wall portion of a first chamber of a charged particle beam device, the charged particle beam device that radiates a charged particle beam passing through an inside of the first chamber that is air-tightly provided to a sample held on a holding unit outside the first chamber so as to scan the sample, the diaphragm member comprising:
a first film portion that air-tightly separates the inside of the first chamber and the outside of the first chamber from each other, when the diaphragm member is attached to the wall portion, in a state where a pressure inside the first chamber is reduced more than a pressure outside the first chamber by an exhaust unit that exhausts the first chamber, and allows the charged particle beam passing through the inside of the first chamber to be transmitted therethrough; and
a second film portion that is formed so as to be positioned on the holding unit side rather than on the first film portion, when the diaphragm member is attached to the wall portion,
wherein the second film portion prevents the sample held on the holding unit and the first film portion from coming into contact with each other.

15. The diaphragm member according to claim 14, comprising:
a substrate; and
an attaching body to which the substrate is attached,
wherein the first film portion and the second film portion are formed on the substrate, and by attaching the attaching body having the substrate attached thereto to the wall portion, the diaphragm member is attached to the wall portion.
